(19) United States
(12) Patent Application Publication
(10) Pub. No.: US 2023/0413686 A1
(43) Pub. Date: Dec. 21, 2023

(54) MAGNETIC SENSOR

(71) Applicant: Panasonic Intellectual Property Management Co., Ltd., Osaka (JP)

(72) Inventors: Yuki OHYAMA, Fukui (JP); Kazuhiro KANDA, Fukui (JP); Masahiko OHBAYASHI, Osaka (JP); Hideyuki TANIGAWA, Osaka (JP); Masataka TAGAWA, Osaka (JP)

(21) Appl. No.: 18/252,311

(22) PCT Filed: Nov. 16, 2021
(86) PCT No.: PCT/JP2021/042086

§ 371 Date: May 9, 2023

Related U.S. Application Data
(60) Provisional application No. 63/117,154, filed on Nov. 23, 2020.

(30) Foreign Application Priority Data
Feb. 16, 2021 (JP) 2021-022906
May 31, 2021 (JP) 2021-091929
Jul. 16, 2021 (JP) 2021-118285

(51) Int. Cl. H10N 50/85; G01B 7/004; G01R 33/09; H10N 50/10

(52) U.S. Cl. CPC H10N 50/85; G01B 7/004; G01R 33/091; H10N 50/10; G01R 33/093; H10N 50/01

(57) ABSTRACT

A magnetic sensor according to the present disclosure includes a plurality of magnetoresistance pattern portions that forms a bridge circuit. The plurality of magnetoresistance pattern portions are arranged side by side in a first direction. Each of the plurality of magnetoresistance pattern portions is formed in a second direction perpendicular to the first direction. Each of the plurality of magnetoresistance pattern portions is formed in a meandering shape when viewed in a third direction perpendicular to both the first direction and the second direction. Centroids of the plurality of magnetoresistance pattern portions are located on a centerline of the plurality of magnetoresistance pattern portions in the second direction when viewed in the third direction.

### TECHNICAL FIELD

The present disclosure generally relates to a magnetic sensor, and more particularly relates to a magnetic sensor including a plurality of magnetoresistance pattern portions.

### BACKGROUND ART

Patent Literature 1 discloses a magnetoresistive element (magnetic sensor) including an insulating substrate (supporting substrate) and a magnetoresistive film provided on the insulating substrate. The magnetoresistive film includes a plurality of double meandering magneto-sensitive pattern units (magnetoresistance pattern portions). The plurality of double meandering magneto-sensitive pattern units are arranged side by side in the direction in which a magnet moves with respect to the magnetoresistive element.

The magnetoresistive element of Patent Literature 1 tends to have an increased size, which is a problem with the magnetoresistive element.

### CITATION LIST

### Patent Literature

Patent Literature 1: JP 2001-141514 A

### SUMMARY OF INVENTION

It is therefore an object of the present disclosure to provide a magnetic sensor with the ability to contribute to downsizing.

A magnetic sensor according to an aspect of the present disclosure is configured to detect a position of a detection target based on a change in magnetic field strength to be caused by relative movement of the detection target in a first direction. The detection target is magnetized in the first direction in a predetermined cycle of magnetization. The magnetic sensor includes a plurality of magnetoresistance pattern portions. The plurality of magnetoresistance pattern portions forms a bridge circuit. The plurality of magnetoresistance pattern portions are arranged side by side in the first direction. Each of the plurality of magnetoresistance pattern portions is formed in a second direction perpendicular to the first direction. Each of the plurality of magnetoresistance pattern portions is formed in a meandering shape when viewed in a third direction perpendicular to both the first direction and the second direction. Centroids of the plurality of magnetoresistance pattern portions are located on a centerline of the plurality of magnetoresistance pattern portions in the second direction when viewed in the third direction.

### BRIEF DESCRIPTION OF DRAWINGS

FIG. 1 is a perspective view illustrating the appearance of a magnetic sensor according to a first embodiment;

FIG. 2 is a cross-sectional view of the magnetic sensor as taken along a plane X-X shown in FIG. 1;

FIG. 3 schematically illustrates a configuration for a detection target for the magnetic sensor;

FIG. 4 is a schematic circuit diagram of the magnetic sensor;

FIG. 5 illustrates an exemplary arrangement of magnetoresistance pattern portions, wiring pattern portions, and terminals in the magnetic sensor;

FIG. 6 illustrates an exemplary arrangement of magnetoresistance pattern portions, wiring pattern portions, and terminals in a magnetic sensor according to a comparative example;

FIG. 7 is a graph showing how the position detection error of a detection target changes with the pattern width of a magnetoresistance pattern portion;

FIG. 8 illustrates an exemplary arrangement of magnetoresistance pattern portions, wiring pattern portions, and terminals in a magnetic sensor according to a first variation of the first embodiment;

FIG. 9 illustrates an exemplary arrangement of magnetoresistance pattern portions, wiring pattern portions, and terminals in a magnetic sensor according to a second variation of the first embodiment;

FIG. 10 illustrates an exemplary arrangement of magnetoresistance pattern portions, wiring pattern portions, and terminals in a magnetic sensor according to a third variation of the first embodiment;

FIG. 11 shows, on a larger scale, the part A1 in FIG. 10;

FIG. 12 shows, on a larger scale, the part B1 in FIG. 10;

FIG. 13 illustrates an exemplary arrangement of magnetoresistance pattern portions, wiring pattern portions, and terminals in a magnetic sensor according to a fourth variation of the first embodiment;

FIG. 14 shows, on a larger scale, the part A2 in FIG. 13;

FIG. 15 shows, on a larger scale, the part B2 in FIG. 13;

FIG. 16 illustrates an exemplary arrangement of magnetoresistance pattern portions, wiring pattern portions, and terminals in a magnetic sensor according to a second embodiment; and

FIG. 17 shows, on a larger scale, the part A3 in FIG. 16.

### DESCRIPTION OF EMBODIMENTS

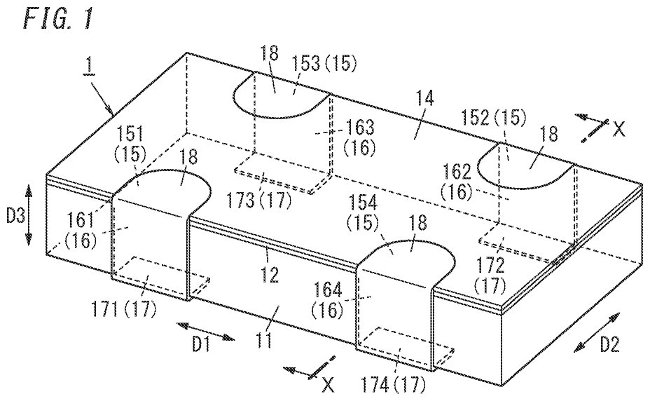

A magnetic sensor 1 according to first and second embodiments will be described with reference to FIGS. 1-17. FIGS. 1-3, 5, 6, and FIGS. 8-17 to be referred to in the following description of embodiments are all schematic representations. Thus, the ratio of the dimensions (including thicknesses) of respective constituent elements illustrated on the drawings does not always reflect their actual dimensional ratio.

### First Embodiment

(1) Overview

First, an overview of a magnetic sensor 1 according to a first embodiment will be described with reference to FIGS. 1-5.

The magnetic sensor 1 detects the position of a detection target 2 using magnetism. The magnetic sensor 1 may be used as, for example, a position sensor such as a linear encoder or a rotary encoder. More specifically, the magnetic sensor 1 may be used as, for example, a position sensor (encoder) for detecting, for example, the position of a camera lens driven by a motor (such as a linear motor or a rotary motor). Alternatively, the magnetic sensor 1 may also be used as, for example, a position sensor for detecting the position of a brake pedal, a brake lever, or a gear shift of an automobile. However, these are only exemplary uses of the magnetic sensor 1 and should not be construed as limiting. As used herein, the “position” to be detected by the magnetic sensor 1 is a concept encompassing both the coordinates of the detection target 2 and the rotational angle defined by the detection target 2 around a rotational axis (virtual axis) passing through the detection target 2 (i.e., the orientation of the detection target 2). That is to say, the magnetic sensor 1 detects at least one of the coordinates of the detection target 2 or the rotational angle defined by the detection target 2.

In the following description, an embodiment in which the magnetic sensor 1 is used as a linear encoder will be described as an example. The linear encoder may be an increment type or an absolute type, whichever is appropriate. In the first embodiment, the magnetic sensor 1 detects the coordinates of the detection target 2.

A magnetic sensor 1 according to the first embodiment is configured to detect the position of a detection target 2 based on a change in magnetic field strength to be caused by relative movement of the detection target 2 in a first direction D1. The detection target 2 is magnetized in the first direction D1 in a predetermined cycle of magnetization λ. The magnetic sensor 1 includes a plurality of magnetoresistance pattern portions 131-134. The plurality of magnetoresistance pattern portions 131-134 forms a bridge circuit. The plurality of magnetoresistance pattern portions 131-134 are arranged side by side in the first direction D1. Each of the plurality of magnetoresistance pattern portions 131-134 is formed in a second direction D2 perpendicular to the first direction D1. Each of the plurality of magnetoresistance pattern portions 131-134 is formed in a meandering shape when viewed in a third direction D3. The third direction D3 is perpendicular to both the first direction D1 and the second direction D2. Centroids c11-c14 of the plurality of magnetoresistance pattern portions 131-134 are located on a centerline L2 of the plurality of magnetoresistance pattern portions 131-134 in the second direction D2 when viewed in the third direction D3. As used herein, if something is “aligned with the first direction or the second direction,” this expression refers to not only a situation where the thing is parallel to the first direction or the second direction but also a situation where the thing forms a predetermined angle (of 5 degrees, for example) with respect to either the first direction or the second direction.

In the magnetic sensor 1 according to the first embodiment, the centroids c11-c14 of the plurality of magnetoresistance pattern portions 131-134 are located on the centerline L2 when viewed in the third direction D3 as described above. This reduces the dimension of the plurality of magnetoresistance pattern portions 131-134 as measured in the second direction D2 compared to a situation where the centroids c11-c14 of the plurality of magnetoresistance pattern portions 131-134 are shifted in the second direction D2 with respect to the centerline L2. Consequently, this contributes to downsizing the magnetic sensor 1. In addition, this also reduces, even if the detection target 2 tilts in the second direction D2 with respect to the magnetic sensor 1, the variations in the resistance value of the plurality of magnetoresistance pattern portions 131-134 due to a dispersion in magnetic field strength distribution among the plurality of magnetoresistance pattern portions 131-134. Consequently, this reduces the position detection error of the detection target 2.

(2) Details

Next, the magnetic sensor 1 according to the first embodiment will be described in further detail with reference to FIGS. 1-7.

(2.1) Structure of Magnetic Sensor

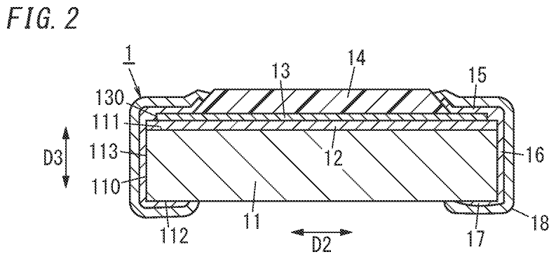

First, the structure of the magnetic sensor 1 according to the first embodiment will be described with reference to FIGS. 1 and 2.

The magnetic sensor 1 according to the first embodiment is formed in the shape of a rectangular parallelepiped elongate in the first direction D1 as shown in FIGS. 1 and 2. In the following description, the first direction D1 is defined by the longitudinal axis (i.e., length) of the magnetic sensor 1, a second direction D2 is defined by the latitudinal axis (i.e., width) of the magnetic sensor 1, and a third direction D3 is defined by the thickness of the magnetic sensor 1. However, these directions should not be construed as limiting the direction in which the magnetic sensor 1 should be used. Also, the arrows indicating these directions D1, D2, and D3 on the drawings are shown there only for illustrative purposes and are insubstantial ones. In the first embodiment, the first direction D1 is a direction in which the magnetic sensor 1 moves with respect to the detection target 2. In the first embodiment, the first direction D1, the second direction D2, and the third direction D3 intersect with each other at right angles.

The magnetic sensor 1 according to the first embodiment includes a supporting substrate 11, a glass glazing layer 12, a magnetoresistive layer 13, and a protective coating 14 as shown in FIGS. 1 and 2. In addition, the magnetic sensor 1 according to the first embodiment further includes a plurality of (e.g., four) upper surface electrodes 15, a plurality of (e.g., four) end face electrodes 16, a plurality of (e.g., four) lower surface electrodes (backside electrodes) 17, and a plurality of (e.g., four) plating layers 18. The plurality of upper surface electrodes 15, the plurality of end face electrodes 16, and the plurality of lower surface electrodes 17 correspond one to one to each other.

The supporting substrate 11 may be a ceramic substrate, for example. A material for the ceramic substrate may be, for example, sintered alumina, of which the content of alumina is equal to or greater than 96%. The supporting substrate 11 is formed in the shape of a rectangular plate which is elongate in the first direction D1 defined by the longitudinal axis of the magnetic sensor 1 when viewed in the third direction D3 defined by the thickness of the magnetic sensor 1. As shown in FIG. 2, the supporting substrate 11 has a first principal surface 111, a second principal surface 112, and outer peripheral surfaces 113. Each of the first principal surface 111 and the second principal surface 112 is a planar surface aligned with both the first direction D1 and the second direction D2. The first principal surface 111 and the second principal surface 112 face each other in the third direction D3. The outer peripheral surfaces 113 are four planar surfaces aligned with the third direction D3.

The glass glazing layer 12 may contain, for example, silicon dioxide as a main component thereof. The glass glazing layer 12 is formed on the first principal surface 111 (refer to FIG. 2) of the supporting substrate 11. Specifically, the glass glazing layer 12 is formed to cover the first principal surface 111 of the supporting substrate 11 in its entirety. The glass glazing layer 12 is formed in the shape of a rectangular layer which is elongate in the first direction D1 when viewed in the third direction D3. In the magnetic sensor 1 according to the first embodiment, the glass glazing layer 12 makes the planar surface, on which the magnetoresistive layer 13 is formed, sufficiently smooth. Note that the glass glazing layer 12 only needs to be provided in a region where the plurality of magnetoresistance pattern portions 131-134 are arranged. Optionally, the glass glazing layer 12 may include a lead oxide.

The magnetoresistive layer 13 is formed on the glass glazing layer 12 as shown in FIG. 2. The magnetoresistive layer 13 includes a plurality of first layers and a plurality of second layers. Each of the plurality of first layers is a magnetic layer and may contain, for example, an NiFeCo alloy. Each of the plurality of second layers is a non-magnetic layer and may contain, for example, a Cu alloy. The plurality of first layers and the plurality of second layers are alternately stacked one on top of another on the glass glazing layer 12. In the magnetic sensor 1 according to the first embodiment, a giant magnetoresistive (GMR) film is formed by the magnetoresistive layer 13. The number of the first layers provided may be the same as, or different from, the number of the second layers provided, whichever is appropriate.

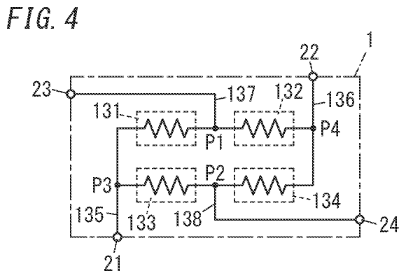

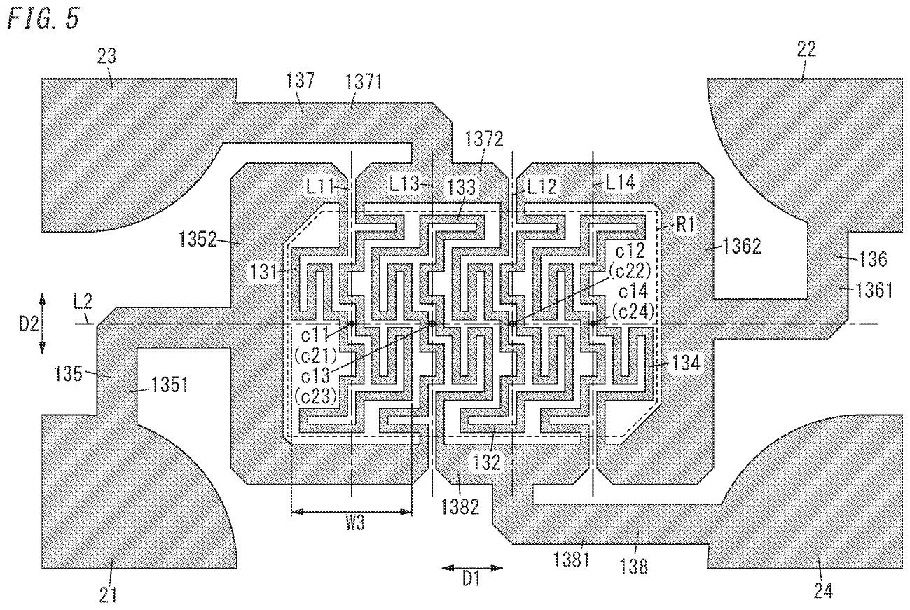

The protective coating 14 is a coating for protecting the magnetoresistive layer 13. A material for the protective coating 14 may be an epoxy resin, for example. The protective coating 14 is formed over the glass glazing layer 12 to cover the magnetoresistive layer 13 partially. In the magnetic sensor 1 according to the first embodiment, the power supply terminal 21 and the ground terminal 22 (to be described later) and the first output terminal 23 and the second output terminal 24 (refer to FIGS. 4 and 5) are each connected to any of the plurality of upper surface electrodes 15. Thus, the protective coating 14 is provided to cover the magnetoresistive layer 13 entirely but at least the power supply terminal 21, the ground terminal 22, the first output terminal 23, and the second output terminal 24.

The plurality of upper surface electrodes 15 are formed on the first principal surface 111 (refer to FIG. 2) of the supporting substrate 11 as shown in FIG. 1. A material for the plurality of upper surface electrodes 15 may be, for example, a CuNi (copper-nickel) based alloy. The plurality of upper surface electrodes 15 includes a first upper surface electrode 151, a second upper surface electrode 152, a third upper surface electrode 153, and a fourth upper surface electrode 154. Each of the plurality of upper surface electrodes 15 is connected to any of the power supply terminal 21, the ground terminal 22, the first output terminal 23, or the second output terminal 24 in the magnetoresistive layer 13. More specifically, among the plurality of upper surface electrodes 15, the first upper surface electrode 151 is connected to the power supply terminal 21. The second upper surface electrode 152 is connected to the ground terminal 22. Also, among the plurality of upper surface electrodes 15, the third upper surface electrode 153 is connected to the first output terminal 23. The fourth upper surface electrode 154 is connected to the second output terminal 24. The plurality of upper surface electrodes 15 may be, for example, a sputtered film formed by sputtering.

The plurality of end face electrodes 16 is formed to cover two outer peripheral surfaces 113 (refer to FIG. 2), which are aligned with the longitudinal axis of the supporting substrate 11, along the longitudinal axis of the supporting substrate 11 (i.e., in the first direction D1) as shown in FIG. 1. A material for the plurality of end face electrodes 16 may be, for example, a CuNi (copper-nickel) based alloy. The plurality of end face electrodes 16 includes a first end face electrode 161, a second end face electrode 162, a third end face electrode 163, and a fourth end face electrode 164. The plurality of end face electrodes 16 correspond one to one to the plurality of upper surface electrodes 15 as described above. More specifically, the first end face electrode 161 corresponds to, and is connected to, the first upper surface electrode 151. The second end face electrode 162 corresponds to, and is connected to, the second upper surface electrode 152. The third end face electrode 163 corresponds to, and is connected to, the third upper surface electrode 153. The fourth end face electrode 164 corresponds to, and is connected to, the fourth upper surface electrode 154. The plurality of end face electrodes 16 may be, for example, a sputtered film formed by sputtering.

The plurality of lower surface electrodes 17 is formed on the second principal surface 112 (refer to FIG. 2) of the supporting substrate 11 as shown in FIG. 1. A material for the plurality of lower surface electrodes 17 may be, for example, a CuNi (copper-nickel) based alloy. The plurality of lower surface electrodes 17 includes a first lower surface electrode 171, a second lower surface electrode 172, a third lower surface electrode 173, and a fourth lower surface electrode 174. The plurality of lower surface electrodes 17 correspond one to one to the plurality of upper surface electrodes 15 and the plurality of end face electrodes 16 as described above. More specifically, the first lower surface electrode 171 corresponds to the first upper surface electrode 151 and the first end face electrode 161 and is connected to the first end face electrode 161. The second lower surface electrode 172 corresponds to the second upper surface electrode 152 and the second end face electrode 162 and is connected to the second end face electrode 162. The third lower surface electrode 173 corresponds to the third upper surface electrode 153 and the third end face electrode 163 and is connected to the third end face electrode 163. The fourth lower surface electrode 174 corresponds to the fourth upper surface electrode 154 and the fourth end face electrode 164 and is connected to the fourth end face electrode 164. The plurality of lower surface electrodes 17 may be, for example, a sputtered film formed by sputtering.

In the magnetic sensor 1 according to the first embodiment, the first upper surface electrode 151, the first end face electrode 161, and the first lower surface electrode 171 are formed in a U-shape when viewed in the first direction D1. The second upper surface electrode 152, the second end face electrode 162, and the second lower surface electrode 172 are formed in a U-shape when viewed in the first direction D1. The third upper surface electrode 153, the third end face electrode 163, and the third lower surface electrode 173 are formed in a U-shape when viewed in the first direction D1. The fourth upper surface electrode 154, the fourth end face electrode 164, and the fourth lower surface electrode 174 are formed in a U-shape when viewed in the first direction D1.

The magnetic sensor 1 according to the first embodiment may be connected to a mount board, on which the magnetic sensor 1 is going to be mounted, via the plurality of lower surface electrodes 17.

Each of the plurality of plating layers 18 is formed to cover a corresponding one of the plurality of upper surface electrodes 15, a corresponding one of the plurality of end face electrodes 16, and a corresponding one of the plurality of lower surface electrodes 17 as shown in FIG. 1. That is to say, each of the plurality of plating layers 18 is formed in a U-shape when viewed in the first direction D1. Each of the plurality of plating layers 18 includes an electroplated copper layer and an electroplated tin layer. Each of the plurality of plating layers 18 is in contact with the protective coating 14 as shown in FIG. 2.

(2.2) Structure of Detection Target

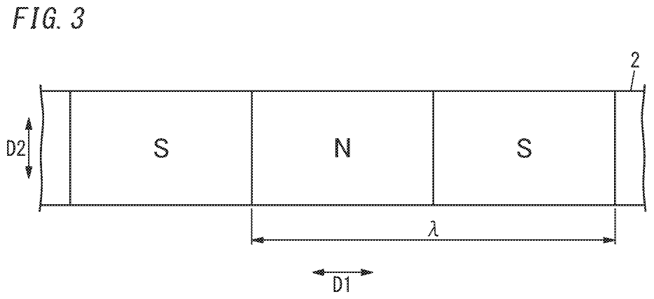

Next, the structure of the detection target 2 will be described with reference to FIG. 3.

The detection target 2 may be a magnetic scale, for example. The detection target 2 is formed in the shape of a plate which is elongate in the first direction D1 as shown in FIG. 3. The detection target 2 faces the magnetic sensor 1 in the third direction D3 (i.e., the direction perpendicular to the paper sheet on which FIG. 3 is drawn).

The detection target 2 includes a plurality of magnetic poles. The plurality of magnetic poles are arranged in the first direction D1. The plurality of magnetic poles includes one or more N poles and one or more S poles. The plurality of magnetic poles are arranged such that the one or more S poles and the one or more N poles are alternately arranged in the first direction D1. Each magnetic pole may be, for example, a ferrite magnet or a neodymium magnet. The detection target 2 includes a plurality of ferrite magnets or a plurality of neodymium magnets which are arranged in the first direction D1. The detection target 2 is magnetized in the first direction D1 in a cycle of magnetization λ as shown in FIG. 3.

(2.3) Circuit Configuration for Magnetic Sensor

Next, a circuit configuration for the magnetic sensor 1 according to the first embodiment will be described with reference to FIG. 4.

The magnetic sensor 1 according to the first embodiment includes the plurality of (e.g., four) magnetoresistance pattern portions 131-134, the first wiring pattern portion 135, the second wiring pattern portion 136, a third wiring pattern portion 137, and a fourth wiring pattern portion 138 as shown in FIG. 4. In addition, the magnetic sensor 1 according to the first embodiment further includes the power supply terminal 21, the ground terminal 22, the first output terminal 23, and the second output terminal 24. The magnetic sensor 1 according to the first embodiment includes four magnetoresistance pattern portions 131-134 as the plurality of magnetoresistance pattern portions 131-134. The four magnetoresistance pattern portions 131-134 consist of a first magnetoresistance pattern portion 131, a second magnetoresistance pattern portion 132, a third magnetoresistance pattern portion 133, and a fourth magnetoresistance pattern portion 134.

The first magnetoresistance pattern portion 131, the second magnetoresistance pattern portion 132, the third magnetoresistance pattern portion 133, and the fourth magnetoresistance pattern portion 134 form a full bridge circuit. Specifically, a series circuit of the first magnetoresistance pattern portion 131 and the second magnetoresistance pattern portion 132 and a series circuit of the third magnetoresistance pattern portion 133 and the fourth magnetoresistance pattern portion 134 are connected to each other in parallel. In other words, the plurality of magnetoresistance pattern portions 131-134 includes the first magnetoresistance pattern portion 131 and second magnetoresistance pattern portion 132 that are connected together in series and the third magnetoresistance pattern portion 133 and fourth magnetoresistance pattern portion 134 that are connected together in series.

A connection node P1 between the first magnetoresistance pattern portion 131 and the second magnetoresistance pattern portion 132 is connected to the first output terminal 23 via the third wiring pattern portion 137. That is to say, the third wiring pattern portion 137 connected to the first output terminal 23 is connected to the first magnetoresistance pattern portion 131 and the second magnetoresistance pattern portion 132 that are connected together in series among the four magnetoresistance pattern portions 131-134. The other end portion (i.e., the left end portion in FIG. 4), located opposite from one end portion adjacent to the second magnetoresistance pattern portion 132, of the first magnetoresistance pattern portion 131 is connected to the power supply terminal 21 via the first wiring pattern portion 135. That is to say, the first wiring pattern portion 135 is connected to the power supply terminal 21. The other end portion (i.e., the right end portion in FIG. 4), located opposite from one end portion adjacent to the first magnetoresistance pattern portion 131, of the second magnetoresistance pattern portion 132 is connected to the ground terminal 22 via the second wiring pattern portion 136. That is to say, the second wiring pattern portion 136 is connected to the ground terminal 22.

A connection node P2 between the third magnetoresistance pattern portion 133 and the fourth magnetoresistance pattern portion 134 is connected to the second output terminal 24 via the fourth wiring pattern portion 138. That is to say, the fourth wiring pattern portion 138 connected to the second output terminal 24 is connected to the third magnetoresistance pattern portion 133 and fourth magnetoresistance pattern portion 134 that are connected together in series among the four magnetoresistance pattern portions 131-134. The other end portion (i.e., the left end portion in FIG. 4), located opposite from one end portion adjacent to the fourth magnetoresistance pattern portion 134, of the third magnetoresistance pattern portion 133 is connected to the power supply terminal 21 via the first wiring pattern portion 135. The other end portion (i.e., the right end portion in FIG. 4), located opposite from one end portion adjacent to the third magnetoresistance pattern portion 133, of the fourth magnetoresistance pattern portion 134 is connected to the ground terminal 22 via the second wiring pattern portion 136.

That is to say, in the magnetic sensor 1 according to the first embodiment, a connection node P3 between the first magnetoresistance pattern portion 131 and the third magnetoresistance pattern portion 133 is connected to the power supply terminal 21 via the first wiring pattern portion 135. In other words, the first wiring pattern portion 135 is connected to the other end portion, located opposite from the end portion adjacent to the second magnetoresistance pattern portion 132, of the first magnetoresistance pattern portion 131 and the other end portion, located opposite from the end portion adjacent to the fourth magnetoresistance pattern portion 134, of the third magnetoresistance pattern portion 133.

In addition, in the magnetic sensor 1 according to the first embodiment, a connection node P4 between the second magnetoresistance pattern portion 132 and the fourth magnetoresistance pattern portion 134 is connected to the ground terminal 22 via the second wiring pattern portion 136. In other words, the second wiring pattern portion 136 is connected to the other end portion, located opposite from the end portion adjacent to the first magnetoresistance pattern portion 131, of the second magnetoresistance pattern portion 132 and the other end portion, located opposite from the end portion adjacent to the third magnetoresistance pattern portion 133, of the fourth magnetoresistance pattern portion 134.

The power supply terminal 21, the ground terminal 22, the first output terminal 23, and the second output terminal 24 correspond one to one to plurality of upper surface electrodes 15. Specifically, the power supply terminal 21 corresponds one to one to, and is connected to, the first upper surface electrode 151 out of the plurality of upper surface electrodes 15. The ground terminal 22 corresponds one to one to, and is connected to, the second upper surface electrode 152 out of the plurality of upper surface electrodes 15. The first output terminal 23 corresponds one to one to, and is connected to, the third upper surface electrode 153 out of the plurality of upper surface electrodes 15. The second output terminal 24 corresponds one to one to, and is connected to, the fourth upper surface electrode 154 out of the plurality of upper surface electrodes 15.

(2.4) Exemplary Arrangement of Magnetoresistance Pattern Portions, Wiring Pattern Portions, and Terminals

Next, an exemplary arrangement of the plurality of magnetoresistance pattern portions 131-134, the first to fourth wiring pattern portions 135-138, and the four terminals 21-24 in the magnetic sensor 1 according to the first embodiment will be described with reference to FIG. 5. In FIG. 5, the plurality of magnetoresistance pattern portions 131-134, the first to fourth wiring pattern portions 135-138, and the four terminals 21-24 are shaded by dot hatching to be easily distinguished.

The plurality of magnetoresistance pattern portions 131-134 are arranged side by side in the first direction D1 defined by the longitudinal axis of the magnetic sensor 1 as shown in FIG. 5. The plurality of magnetoresistance pattern portions 131-134 consists of the first magnetoresistance pattern portion 131, the second magnetoresistance pattern portion 132, the third magnetoresistance pattern portion 133, and the fourth magnetoresistance pattern portion 134 as described above.

Each of the first magnetoresistance pattern portion 131, the second magnetoresistance pattern portion 132, the third magnetoresistance pattern portion 133, and the fourth magnetoresistance pattern portion 134 is formed in a meandering shape when viewed in the third direction D3 (i.e., the direction perpendicular to the paper sheet on which FIG. 5 is drawn). As used herein, the expression “each of the first magnetoresistance pattern portion 131, the second magnetoresistance pattern portion 132, the third magnetoresistance pattern portion 133, and the fourth magnetoresistance pattern portion 134 is formed in a meandering shape” means that when viewed in the third direction D3, each of the first magnetoresistance pattern portion 131, the second magnetoresistance pattern portion 132, the third magnetoresistance pattern portion 133, and the fourth magnetoresistance pattern portion 134 is not formed to extend straight in the second direction D2 but formed to meander at least in the first direction D1. Each of the first magnetoresistance pattern portion 131, the second magnetoresistance pattern portion 132, the third magnetoresistance pattern portion 133, and the fourth magnetoresistance pattern portion 134 is formed in the second direction D2 as shown in FIG. 5. That is to say, the longitudinal axis of each of the first magnetoresistance pattern portion 131, the second magnetoresistance pattern portion 132, the third magnetoresistance pattern portion 133, and the fourth magnetoresistance pattern portion 134 is aligned with the second direction D2. In addition, each of the first magnetoresistance pattern portion 131, the second magnetoresistance pattern portion 132, the third magnetoresistance pattern portion 133, and the fourth magnetoresistance pattern portion 134 is made up of parts falling within a region R1 as shown in FIG. 5.

In the magnetic sensor 1 according to the first embodiment, the plurality of magnetoresistance pattern portions 131-134 are arranged in the first direction D1 in the order of the first magnetoresistance pattern portion 131, the third magnetoresistance pattern portion 133, the second magnetoresistance pattern portion 132, and the fourth magnetoresistance pattern portion 134 from left to right as shown in FIG. 5. In addition, in the magnetic sensor 1 according to the first embodiment, the plurality of magnetoresistance pattern portions 131-134 are formed in the same shape when viewed in the third direction D3. As used herein, if two things “have the same shape,” this expression refers to not only a situation where the two things have exactly the same shape but also a situation where their shapes are different to the extent that variations in their resistance value in response to a change in magnetic field strength distribution may be regarded as the same behavior. Therefore, the plurality of magnetoresistance pattern portions 131-134 may have mutually different shapes as long as variations in their resistance value in response to a change in magnetic field strength distribution may be regarded as the same behavior.

The first wiring pattern portion 135 connects together the first magnetoresistance pattern portion 131 and the power supply terminal 21 and also connects together the third magnetoresistance pattern portion 133 and the power supply terminal 21 as shown in FIG. 5. The first wiring pattern portion 135 includes a first wiring portion 1351 and a second wiring portion 1352. The first wiring portion 1351 is formed in an L-shape when viewed in the third direction D3 and is connected to the power supply terminal 21 at a first end portion thereof. The second wiring portion 1352 is formed in a U-shape when viewed in the third direction D3 and connected to a second end portion of the first wiring portion 1351. A first end portion of the second wiring portion 1352 is connected to a first end portion of the first magnetoresistance pattern portion 131. A second end portion of the second wiring portion 1352 is connected to a first end portion of the third magnetoresistance pattern portion 133.

The second wiring pattern portion 136 connects together the second magnetoresistance pattern portion 132 and the ground terminal 22 and also connects together the fourth magnetoresistance pattern portion 134 and the ground terminal 22 as shown in FIG. 5. The second wiring pattern portion 136 includes a first wiring portion 1361 and a second wiring portion 1362. The first wiring portion 1361 is formed in an L-shape when viewed in the third direction D3 and is connected to the ground terminal 22 at a first end portion thereof. The second wiring portion 1362 is formed in a U-shape when viewed in the third direction D3 and connected to a second end portion of the first wiring portion 1361. A first end portion of the second wiring portion 1362 is connected to a first end portion of the second magnetoresistance pattern portion 132. A second end portion of the second wiring portion 1362 is connected to a first end portion of the fourth magnetoresistance pattern portion 134.

The third wiring pattern portion 137 connects together the first magnetoresistance pattern portion 131 and the first output terminal 23 and also connects together the second magnetoresistance pattern portion 132 and the first output terminal 23 as shown in FIG. 5. The third wiring pattern portion 137 includes a first wiring portion 1371 and a second wiring portion 1372. The first wiring portion 1371 is formed in an L-shape when viewed in the third direction D3 and is connected to the first output terminal 23 at a first end portion thereof. The second wiring portion 1372 is formed in a shape elongate in the first direction D1 when viewed in the third direction D3 and connected to a second end portion of the first wiring portion 1371. A first end portion of the second wiring portion 1372 is connected to a second end portion of the first magnetoresistance pattern portion 131. A second end portion of the second wiring portion 1372 is connected to a second end portion of the second magnetoresistance pattern portion 132.

The fourth wiring pattern portion 138 connects together the third magnetoresistance pattern portion 133 and the second output terminal 24 and also connects together the fourth magnetoresistance pattern portion 134 and the second output terminal 24 as shown in FIG. 5. The fourth wiring pattern portion 138 includes a first wiring portion 1381 and a second wiring portion 1382. The first wiring portion 1381 is formed in an L-shape when viewed in the third direction D3 and is connected to the second output terminal 24 at a first end portion thereof. The second wiring portion 1382 is formed in a shape elongate in the first direction D1 when viewed in the third direction D3 and connected to a second end portion of the first wiring portion 1381. A first end portion of the second wiring portion 1382 is connected to a second end portion of the third magnetoresistance pattern portion 133. A second end portion of the second wiring portion 1382 is connected to a second end portion of the fourth magnetoresistance pattern portion 134.

In the magnetic sensor 1 according to the first embodiment, the plurality of magnetoresistance pattern portions 131-134 falls within the region surrounded with the second wiring portion 1352 of the first wiring pattern portion 135, the second wiring portion 1362 of the second wiring pattern portion 136, the second wiring portion 1372 of the third wiring pattern portion 137, and the second wiring portion 1382 of the fourth wiring pattern portion 138 as shown in FIG. 5.

In addition, in the magnetic sensor 1 according to the first embodiment, the magnetoresistive layer 13 forms the plurality of magnetoresistance pattern portions 131-134, the first to fourth wiring pattern portions 135-138, and the fourth terminals 21-24. That is to say, in the magnetic sensor 1 according to the first embodiment, the first to fourth wiring pattern portions 135-138 and the fourth terminals 21-24 are made of the same material as the plurality of magnetoresistance pattern portions 131-134.

In the first embodiment, as the magnetic sensor 1 moves in the first direction D1 with respect to the detection target 2, for example, the strength of the magnetic field between the magnetic sensor 1 and the detection target 2 changes. In response to this change in the magnetic field strength, the resistance values of the plurality of magnetoresistance pattern portions 131-134 vary. Then, the position of the detection target 2 may be detected by detecting potentials at the first output terminal 23 and the second output terminal 24. Note that the magnetic sensor 1 and the detection target 2 may be configured to move relative to each other. Thus, the magnetic sensor 1 and the detection target 2 may also be configured such that the detection target 2 moves relative to the magnetic sensor 1.

(2.5) Configuration for Magnetoresistance Pattern Portions

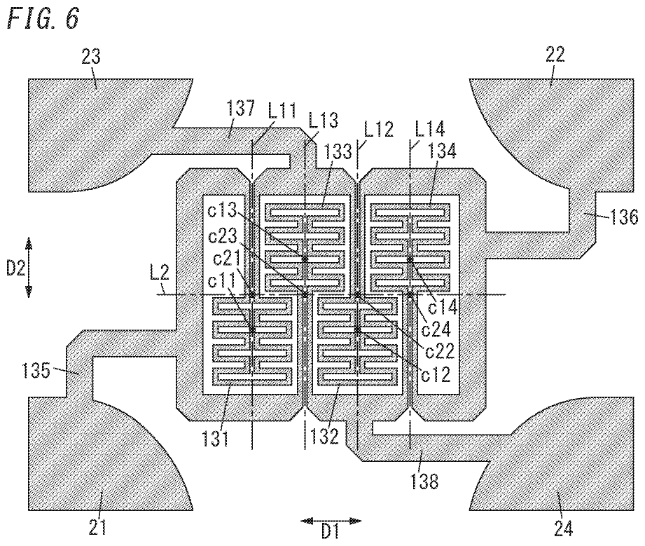

Next, a configuration for each of the plurality of magnetoresistance pattern portions 131-134 will be described with reference to FIGS. 5 and 6. FIG. 6 illustrates an exemplary arrangement of a plurality of magnetoresistance pattern portions 131-134, first to fourth wiring pattern portions 135-138, and four terminals 21-24 in a magnetic sensor according to a comparative example.

In the magnetic sensor according to this comparative example, each of the plurality of magnetoresistance pattern portions 131-134 includes a straight portion and a meandering portion. The straight portion is formed to extend straight in the second direction D2. The meandering portion is formed to meander in the second direction D2. In each of the plurality of magnetoresistance pattern portions 131-134, the straight portion and the meandering portion are arranged one on top of another in the second direction D2. More specifically, in each of the first magnetoresistance pattern portion 131 and the second magnetoresistance pattern portion 132, the straight portion thereof is located at one end (i.e., the upper end in FIG. 6) in the second direction D2 and the meandering portion thereof is located at the other end (i.e., the lower end in FIG. 6) in the second direction D2. On the other hand, in each of the third magnetoresistance pattern portion 133 and the fourth magnetoresistance pattern portion 134, the meandering portion thereof is located at one end (i.e., the upper end in FIG. 6) in the second direction D2 and the straight portion thereof is located at the other end (i.e., the lower end in FIG. 6) in the second direction D2.

In this case, the reference sign “c21” shown in FIGS. 5 and 6 denotes the center of the first magnetoresistance pattern portion 131 as viewed in the third direction D3. The reference sign “c22” shown in FIGS. 5 and 6 denotes the center of the second magnetoresistance pattern portion 132 as viewed in the third direction D3. The reference sign “c23” shown in FIGS. 5 and 6 denotes the center of the third magnetoresistance pattern portion 133 as viewed in the third direction D3. The reference sign “c24” shown in FIGS. 5 and 6 denotes the center of the fourth magnetoresistance pattern portion 134 as viewed in the third direction D3. As used herein, the “center of the magnetoresistance pattern portion” in each of the plurality of magnetoresistance pattern portions refers to the center of a rectangular area surrounded with two straight lines passing through both ends of the magnetoresistance pattern portion in the first direction D1 and extending in the second direction D2 when viewed in the third direction D3 and two straight lines passing through both ends of the magnetoresistance pattern portion in the second direction D2 and extending in the first direction D1 when viewed in the third direction D3. As used herein, “both ends of the magnetoresistance pattern portion in the first direction D1” respectively refer to the leftmost part of the magnetoresistance pattern portion and the rightmost part of the magnetoresistance pattern portion in FIGS. 5 and 6. Meanwhile, “both ends of the magnetoresistance pattern portion in the second direction D2” respectively refer to the uppermost part of the magnetoresistance pattern portion and the lowermost part of the magnetoresistance pattern portion in FIGS. 5 and 6. Therefore, the center c21 of the first magnetoresistance pattern portion 131 is the intersection between its centerline L11 in the first direction D1 and its centerline L2 in the second direction D2. The center c22 of the second magnetoresistance pattern portion 132 is the intersection between its centerline L12 in the first direction D1 and its centerline L2 in the second direction D2. The center c23 of the third magnetoresistance pattern portion 133 is the intersection between its centerline L13 in the first direction D1 and its centerline L2 in the second direction D2. The center c24 of the fourth magnetoresistance pattern portion 134 is the intersection between its centerline L14 in the first direction D1 and its centerline L2 in the second direction D2.

On the other hand, the reference sign “c11” shown in FIGS. 5 and 6 denotes the centroid of the first magnetoresistance pattern portion 131. The reference sign “c12” shown in FIGS. 5 and 6 denotes the centroid of the second magnetoresistance pattern portion 132. The reference sign “c13” shown in FIGS. 5 and 6 denotes the centroid of the third magnetoresistance pattern portion 133. The reference sign “c14” shown in FIGS. 5 and 6 denotes the centroid of the fourth magnetoresistance pattern portion 134. As used herein, the “centroid of the magnetoresistance pattern portion” in each of the plurality of magnetoresistance pattern portions refers to a point (x₀, y₀) defining the center of figure of a part where the resistance value varies and satisfying the following Equations (1) and (2):

$$\begin{matrix}{x}_{0} = \frac{{\int }_{A} {x}_{1} dA}{A} & ( 1 ) \\ {y}_{0} = \frac{{\int }_{A} {y}_{1} dA}{A} & ( 2 )\end{matrix}$$

In these Equations (1) and (2), x₀ is a coordinate of the centroid in the first direction D1, y₀ is a coordinate of the centroid in the second direction D2, x₁ is a coordinate of an arbitrary point of the magnetoresistance pattern portion in the first direction D1, y₁ is a coordinate of an arbitrary point of the magnetoresistance pattern portion in the second direction D2, A is the area of the magnetoresistance pattern portion, and dA is the small area of the point (x₁, y₁).

In the magnetic sensor according to the comparative example, the centroid c11 of the first magnetoresistance pattern portion 131 is located, in the second direction D2, on the meandering portion side (i.e., located on the lower side in FIG. 6) with respect to the center c21 of the first magnetoresistance pattern portion 131. The centroid c12 of the second magnetoresistance pattern portion 132 is located, in the second direction D2, on the meandering portion side (i.e., located on the lower side in FIG. 6) with respect to the center c22 of the second magnetoresistance pattern portion 132. The centroid c13 of the third magnetoresistance pattern portion 133 is located, in the second direction D2, on the meandering portion side (i.e., located on the upper side in FIG. 6) with respect to the center c23 of the third magnetoresistance pattern portion 133. The centroid c14 of the fourth magnetoresistance pattern portion 134 is located, in the second direction D2, on the meandering portion side (i.e., located on the upper side in FIG. 6) with respect to the center c24 of the fourth magnetoresistance pattern portion 134. That is to say, in the magnetic sensor according to the comparative example, when viewed in the third direction D3 (i.e., the direction perpendicular to the paper sheet on which FIG. 6 is drawn), none of the centroids c11-c14 of the plurality of magnetoresistance pattern portions 131-134 are located on the centerline L2 of the plurality of magnetoresistance pattern portions 131-134 in the second direction D2.

In the magnetic sensor according to the comparative example, the centroids c11-c14 of the magnetoresistance pattern portions 131-134 are not located on the centerline L2 but are shifted in the second direction D2. This causes, when the detection target 2 tilts in the second direction D2 with respect to the magnetic sensor, for example, a dispersion in magnetic field strength distribution among the plurality of magnetoresistance pattern portions 131-134, thus causing a dispersion in resistance value among the plurality of magnetoresistance pattern portions 131-134 as well. Consequently, this causes an increase in the position detection error of the detection target 2.

On the other hand, in the magnetic sensor 1 according to the first embodiment, the center c21 of the first magnetoresistance pattern portion 131 agrees with its centroid c11 and the center c22 of the second magnetoresistance pattern portion 132 agrees with its centroid c12 as shown in FIG. 5. In addition, in the magnetic sensor 1 according to the first embodiment, the center c23 of the third magnetoresistance pattern portion 133 agrees with its centroid c13 and the center c24 of the fourth magnetoresistance pattern portion 134 agrees with its centroid c14. That is to say, in the magnetic sensor 1 according to the first embodiment, the respective centroids c11-c14 of the plurality of magnetoresistance pattern portions 131-134 are located on the centerline (center axis) L2 of the plurality of magnetoresistance pattern portions 131-134 in the second direction D2 when viewed in the third direction D3 as shown in FIG. 5. The centerline L2 is aligned with the first direction D1. This reduces, even when the detection target 2 tilts in the second direction D2 with respect to the magnetic sensor 1, the variations in the resistance value of the plurality of magnetoresistance pattern portions 131-134 due to a dispersion in magnetic field strength distribution among the plurality of magnetoresistance pattern portions 131-134. Consequently, this reduces the position detection error of the detection target 2. In addition, this allows, compared to a situation where the centroids c11-c14 of the plurality of magnetoresistance pattern portions 131-134 shift in the second direction D2 with respect to the centerline L2, the plurality of magnetoresistance pattern portions 131-134 to have a smaller dimension in the second direction D2, thus contributing to downsizing the magnetic sensor 1 in the second direction D2.

Furthermore, in the magnetic sensor 1 according to the first embodiment, each of the plurality of magnetoresistance pattern portions 131-134 is formed in the meandering shape when viewed in the third direction D3 as described above. More specifically, each of the plurality of magnetoresistance pattern portions 131-134 is adjacent, in the first direction D1, to a neighboring magnetoresistance pattern portion and includes a part protruding in the first direction D1 toward the neighboring magnetoresistance pattern portion to overlap, in the second direction D2, with a part of the neighboring magnetoresistance pattern portion. Specifically, part of the first magnetoresistance pattern portion 131 protrudes toward the third magnetoresistance pattern portion 133 adjacent to the first magnetoresistance pattern portion 131 in the first direction D1. Two parts of the second magnetoresistance pattern portion 132 respectively protrude toward the third magnetoresistance pattern portion 133 and the fourth magnetoresistance pattern portion 134 adjacent to the second magnetoresistance pattern portion 132 in the first direction D1. Two parts of the third magnetoresistance pattern portion 133 respectively protrude toward the first magnetoresistance pattern portion 131 and the second magnetoresistance pattern portion 132 adjacent to the third magnetoresistance pattern portion 133 in the first direction D1. Part of the fourth magnetoresistance pattern portion 134 protrudes toward the second magnetoresistance pattern portion 132 adjacent to the fourth magnetoresistance pattern portion 134 in the first direction D1. As can be seen, letting each of the plurality of magnetoresistance pattern portions 131-134 protrude in the first direction D1 broadens the pattern width W3 of each magnetoresistance pattern portion 131-134. As used herein, the “pattern width” refers to the length of the interval between two straight lines passing through both ends of a magnetoresistance pattern portion in the first direction D1 and extending in the second direction D2 when viewed in the third direction D3.

In this case, if the pattern width W3 of each of the plurality of magnetoresistance pattern portions 131-134 were less than 15% of the cycle of magnetization λ of the detection target 2, for example, then the detection target 2 would react so steeply to a change in magnetic field strength while moving relatively in the first direction D1 as to cause a significant increase in error due to waveform distortion. On the other hand, if the pattern width W3 of each of the plurality of magnetoresistance pattern portions 131-134 were greater than 25% of the cycle of magnetization 2 of the detection target 2, then two adjacent magnetoresistance pattern portions would react to the same magnetic pole of the detection target 2, thus possibly causing a decline in the positioning accuracy of the detection target 2. For these reasons, the pattern width W3 of each of the plurality of magnetoresistance pattern portions 131-134 is preferably equal to or greater than 15% and equal to or less than 25% of the cycle of magnetization λ f the detection target 2. The magnetic sensor 1 according to the first embodiment lets each of the plurality of magnetoresistance pattern portions 131-134 partially protrude in the first direction D1 as described above, thus making the pattern width W3 of each magnetoresistance pattern portion 131-134 equal to or greater than 15% and equal to or less than 25% of the cycle of magnetization λ of the detection target 2.

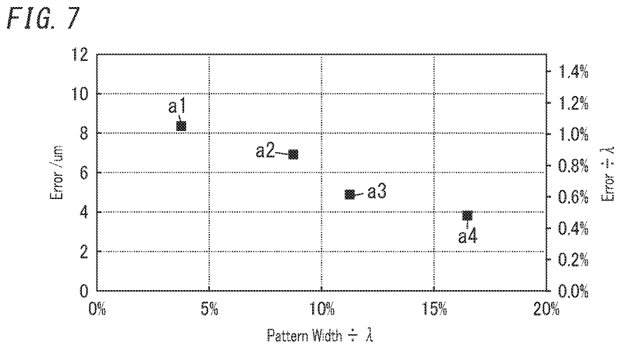

FIG. 7 is a graph showing how the position detection error of the detection target 2 changes with the pattern width W3 of each magnetoresistance pattern portion 131-134. In FIG. 7, the abscissa indicates the ratio (%) of the pattern width W3 to the cycle of magnetization λ of the detection target 2. In FIG. 7, the ordinate on the left side indicates the position detection error (μm) of the detection target 2. In FIG. 7, the ordinate on the right side indicates the ratio (%) of the position detection error of the detection target 2 to the cycle of magnetization λ of the detection target 2. In the example shown in FIG. 7, the cycle of magnetization λ of the detection target 2 may be 800 μm, for example.

At the point a1 shown in FIG. 7, the pattern width W3 of each magnetoresistance pattern portion 131-134 is 30 μm and the ratio of the pattern width W3 to the cycle of magnetization λ is 4%. In that case, the position detection error of the detection target 2 is 8.35 μm and the ratio of the detection error to the cycle of magnetization λ is 1.04%.

At the point a2 shown in FIG. 7, the pattern width W3 of each magnetoresistance pattern portion 131-134 is 70 μm and the ratio of the pattern width W3 to the cycle of magnetization λ is 9%. In that case, the position detection error of the detection target 2 is 6.91 μm and the ratio of the detection error to the cycle of magnetization λ is 0.86%.

At the point a3 shown in FIG. 7, the pattern width W3 of each magnetoresistance pattern portion 131-134 is 90 μm and the ratio of the pattern width W3 to the cycle of magnetization λ is 11%. In that case, the position detection error of the detection target 2 is 4.89 μm and the ratio of the detection error to the cycle of magnetization λ is 0.61%.

At the point a4 shown in FIG. 7, the pattern width W3 of each magnetoresistance pattern portion 131-134 is 132 μm and the ratio of the pattern width W3 to the cycle of magnetization λ is 17%. In that case, the position detection error of the detection target 2 is 3.80 μm and the ratio of the detection error to the cycle of magnetization λ is 0.48%.

As can be seen from the foregoing description, setting the ratio of the pattern width W3 to the cycle of magnetization λ at 15% or more may make the ratio of the detection error to the cycle of magnetization λ equal to or less than 0.5%.

(3) Method for Manufacturing Magnetic Sensor

Next, a method for manufacturing a magnetic sensor 1 according to the first embodiment will be described.

The method for manufacturing the magnetic sensor 1 includes the following first through ninth steps.

A first step includes providing a supporting substrate 11. More specifically, the first step includes providing a wafer, which forms the basis of respective supporting substrates 11 of a plurality of magnetic sensors 1. The wafer may be a ceramic wafer, for example. A material for the ceramic wafer used as an exemplary wafer may be, for example, sintered alumina, of which the content of alumina is equal to or greater than 96%.

A second step includes forming a glass glazing layer 12 on the first principal surface of the wafer. The first principal surface of the wafer is a surface that will be the first principal surface 111 of the supporting substrate 11 in each of the plurality of magnetic sensors 1. More specifically, the second step includes forming the glass glazing layer 12 by applying a glass paste onto the first principal surface 111 of the supporting substrate 11 and then firing the glass paste.

A third step includes forming a magnetoresistive layer 13 for the plurality of magnetic sensors 1. More specifically, the third step includes forming the magnetoresistive layer 13 on the glass glazing layer 12 by sputtering, for example. In the magnetic sensor 1 according to the first embodiment, the magnetoresistive layer 13 is formed as a GMR film as described above by alternately stacking a plurality of NiFeCo alloy layers (first layers) and a plurality of Cu alloy layers (second layers) as described above.

A fourth step includes forming a protective coating 14. More specifically, the fourth step includes applying an epoxy resin by screen printing onto the glass glazing layer 12 such that the magnetoresistive layer 13 is partially covered with the epoxy resin and then thermally curing the epoxy resin, thereby forming the protective coating 14. In this process step, the protective coating 14 is formed to cover the magnetoresistive layer 13 entirely but at least the power supply terminal 21, the ground terminal 22, the first output terminal 23, and the second output terminal 24.

A fifth step includes forming a plurality of upper surface electrodes 15 on the first principal surface of the wafer for each of the plurality of magnetic sensors 1. More specifically, the fifth step includes forming a CuNi based alloy film on the first principal surface of the wafer by sputtering, for example, thereby forming the plurality of upper surface electrodes 15 for each of the plurality of magnetic sensors 1.

A sixth step includes forming a plurality of lower surface electrodes 17 on the second principal surface of the wafer for each of the plurality of magnetic sensors 1. More specifically, the sixth step includes forming a CuNi based alloy film on the second principal surface of the wafer by sputtering, for example, thereby forming the plurality of lower surface electrodes 17 for each of the plurality of magnetic sensors 1. The second principal surface of the wafer is a surface that will be the second principal surface 112 of the supporting substrate 11 in each of the plurality of magnetic sensors 1.

A seventh step includes cutting off the assembly of the plurality of magnetic sensors 1 that have been formed integrally by performing the first through sixth steps into respective magnetic sensors 1. More specifically, the seventh step includes cutting off, by laser cutting or dicing, for example, the assembly of the plurality of magnetic sensors 1 that have been formed integrally into respective magnetic sensors 1.

An eighth step includes forming a plurality of end face electrodes 16 on each magnetic sensor 1 that has been cut off. More specifically, the eighth step includes forming a CuNi based alloy film on the outer peripheral surfaces 113 of the supporting substrate 11 by sputtering, for example, thereby forming a plurality of end face electrodes 16 on each of the plurality of magnetic sensors 1. This allows the plurality of upper surface electrodes 15 and the plurality of lower surface electrodes 17 to be connected together via the plurality of end face electrodes 16.

A ninth step includes forming plating layers 18 on each of the plurality of magnetic sensors 1. More specifically, the ninth step includes sequentially forming an electroplated copper layer and an electroplated tin layer as the plating layers 18 with respect to each of the plurality of magnetic sensors 1.

The magnetic sensor 1 according to the exemplary embodiment may be manufactured by performing the first through ninth steps described above.

(4) Advantages

In the magnetic sensor 1 according to the first embodiment, the respective centroids c11-c14 of the plurality of magnetoresistance pattern portions 131-134 are located on the centerline L2 of the plurality of magnetoresistance pattern portions 131-134 in the second direction D2 when viewed in the third direction D3 as described above. Consequently, this contributes to, compared to a situation where the centroids c11-c14 of the plurality of magnetoresistance pattern portions 131-134 shift in the second direction D2 with respect to the centerline L2, reducing the size of the magnetic sensor 1 in the second direction D2. In addition, this minimizes the error to be caused by the shift of the centroids c11-14 of the respective magnetoresistance pattern portions 131-134 with respect to the centerline L2. Consequently, this enables reducing the position detection error of the detection target 2.

In addition, in the magnetic sensor 1 according to the first embodiment, the pattern width W3 (refer to FIG. 5) of each of the plurality of magnetoresistance pattern portions 131-134 is equal to or greater than 15% of the cycle of magnetization λ (refer to FIG. 3) of the detection target 2. This makes the reaction of the detection target 2 to a change in flux density due to its relative movement much less steep than in a situation where the pattern width W3 of each of the plurality of magnetoresistance pattern portions 131-134 is less than 15% of the cycle of magnetization λ of the detection target 2. Consequently, this reduces the error to be caused by waveform distortion.

Furthermore, in the magnetic sensor 1 according to the first embodiment, each of the plurality of magnetoresistance pattern portions 131-134 is adjacent, in the first direction D1, to a neighboring magnetoresistance pattern portion and includes a part protruding in the first direction D1 toward the neighboring magnetoresistance pattern portion to overlap, in the second direction D2, with a part of the neighboring magnetoresistance pattern portion. This shortens the gap distance between adjacent ones of the magnetoresistance pattern portions 131-134, thus contributing to further downsizing the magnetic sensor 1.

Furthermore, if the pattern width W3 of each of the plurality of magnetoresistance pattern portions 131-134 were greater than 25% of the cycle of magnetization λ of the detection target 2, then two adjacent magnetoresistance pattern portions would react simultaneously to the same magnetic pole of the detection target 2, thus possibly causing a decline in the positioning accuracy of the detection target 2. In contrast, in the magnetic sensor 1 according to the first embodiment, the pattern width W3 of each of the plurality of magnetoresistance pattern portions 131-134 is equal to or less than 25% of the cycle of magnetization λ of the detection target 2 as described above. This significantly reduces the chances of two adjacent magnetoresistance pattern portions reacting simultaneously to the same magnetic pole of the detection target 2, thus reducing the chances of causing a decline in the positioning accuracy of the detection target 2.

Furthermore, in the magnetic sensor 1 according to the first embodiment, in each of the plurality of magnetoresistance pattern portions 131-134, its center c21-c24 agrees with its centroid c11-c14 when viewed in the third direction D3 as described above. This minimizes the error to be caused by the shift between the centers c21-c24 of the plurality of magnetoresistance pattern portions 131-134 and their centroids c11-c14.

Furthermore, in the magnetic sensor 1 according to the first embodiment, each of the plurality of magnetoresistance pattern portions 131-134 is adjacent, in the first direction D1, to a neighboring magnetoresistance pattern portion and includes a part protruding in the first direction D1 toward the neighboring magnetoresistance pattern portion to overlap, in the second direction D2, with a part of the neighboring magnetoresistance pattern portion. This makes the pattern width W3 of each of the plurality of magnetoresistance pattern portions 131-134 equal to or greater than 15% of the cycle of magnetization λ f the detection target 2.

(5) Variations

Note that the first embodiment described above is only an exemplary one of various embodiments of the present disclosure and should not be construed as limiting. Rather, the first embodiment may be readily modified in various manners depending on a design choice or any other factor without departing from the scope of the present disclosure. Next, variations of the first embodiment will be enumerated one after another. Note that the variations to be described below may be adopted in combination as appropriate.

(5.1) First Variation

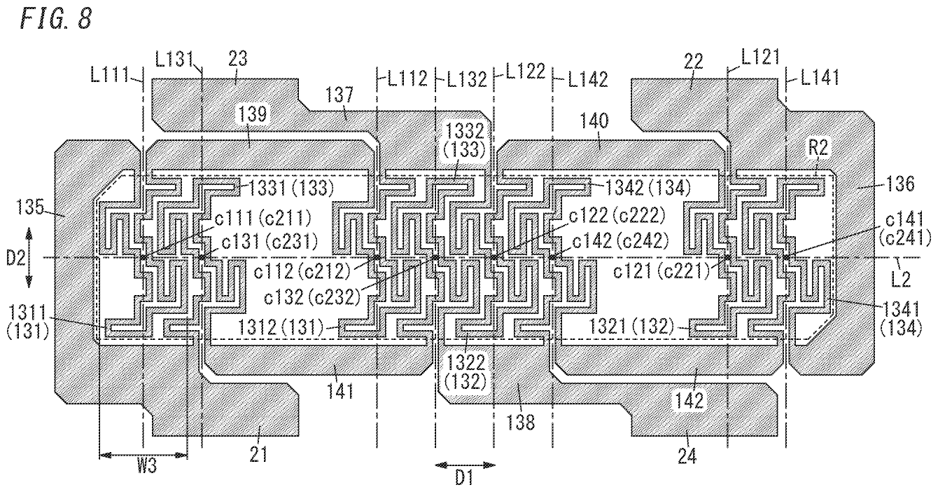

In a magnetic sensor according to a first variation, each of the plurality of magnetoresistance pattern portions 131-134 is made up of a plurality of resistance portions, which is a difference from the magnetic sensor 1 according to the first embodiment described above. In the other respects, the magnetic sensor according to the first variation is the same as the magnetic sensor 1 according to the first embodiment described above. Thus, any constituent element of this first variation, having the same function as a counterpart of the first embodiment described above, will be designated by the same reference numeral as that counterpart's, and description thereof will be omitted herein. A magnetic sensor according to the first variation will now be described with reference to FIG. 8.

The magnetic sensor according to the first variation includes the plurality of (e.g., four) magnetoresistance pattern portions 131-134, first to eighth wiring pattern portions 135-142, the power supply terminal 21, the ground terminal 22, the first output terminal 23, and the second output terminal 24 as shown in FIG. 8. The plurality of magnetoresistance pattern portions 131-134 consists of the first magnetoresistance pattern portion 131, the second magnetoresistance pattern portion 132, the third magnetoresistance pattern portion 133, and the fourth magnetoresistance pattern portion 134.

The first magnetoresistance pattern portion 131 includes a first resistance portion 1311 and a second resistance portion 1312. Each of the first resistance portion 1311 and the second resistance portion 1312 is formed in a meandering shape when viewed in the third direction D3 (i.e., the direction perpendicular to the paper sheet on which FIG. 8 is drawn). A first end portion of the first resistance portion 1311 is connected to the power supply terminal 21 via the first wiring pattern portion 135. A second end portion of the first resistance portion 1311 is connected to a second end portion of the second resistance portion 1312 via the fifth wiring pattern portion 139. A first end portion of the second resistance portion 1312 is connected to the first output terminal 23 via the third wiring pattern portion 137.

The second magnetoresistance pattern portion 132 includes a first resistance portion 1321 and a second resistance portion 1322. Each of the first resistance portion 1321 and the second resistance portion 1322 is formed in a meandering shape when viewed in the third direction D3. A first end portion of the first resistance portion 1321 is connected to the ground terminal 22 via the second wiring pattern portion 136. A second end portion of the first resistance portion 1321 is connected to a second end portion of the second resistance portion 1322 via the sixth wiring pattern portion 140. A first end portion of the second resistance portion 1322 is connected to the first output terminal 23 via the third wiring pattern portion 137.

The third magnetoresistance pattern portion 133 includes a first resistance portion 1331 and a second resistance portion 1332. Each of the first resistance portion 1331 and the second resistance portion 1332 is formed in a meandering shape when viewed in the third direction D3. A first end portion of the first resistance portion 1331 is connected to the power supply terminal 21 via the first wiring pattern portion 135. A second end portion of the first resistance portion 1331 is connected to a second end portion of the second resistance portion 1332 via the seventh wiring pattern portion 141. A first end portion of the second resistance portion 1332 is connected to the second output terminal 24 via the fourth wiring pattern portion 138.

The fourth magnetoresistance pattern portion 134 includes a first resistance portion 1341 and a second resistance portion 1342. Each of the first resistance portion 1341 and the second resistance portion 1342 is formed in a meandering shape when viewed in the third direction D3. A first end portion of the first resistance portion 1341 is connected to the ground terminal 22 via the second wiring pattern portion 136. A second end portion of the first resistance portion 1341 is connected to a second end portion of the second resistance portion 1342 via the eighth wiring pattern portion 142. A first end portion of the second resistance portion 1342 is connected to the second output terminal 24 via the fourth wiring pattern portion 138. In the magnetic sensor according to the first variation, the first magnetoresistance pattern portion 131, the second magnetoresistance pattern portion 132, the third magnetoresistance pattern portion 133, and the fourth magnetoresistance pattern portion 134 are respective portions all falling within the region R2 shown in FIG. 8.

In the magnetic sensor according to the first variation, the center c211 of the first resistance portion 1311 of the first magnetoresistance pattern portion 131 agrees with the centroid c211 thereof when viewed in the third direction D3 and the center c212 of the second resistance portion 1312 of the first magnetoresistance pattern portion 131 agrees with the centroid c212 thereof when viewed in the third direction D3. Also, the center c221 of the first resistance portion 1321 of the second magnetoresistance pattern portion 132 agrees with the centroid c121 thereof when viewed in the third direction D3 and the center c222 of the second resistance portion 1322 of the second magnetoresistance pattern portion 132 agrees with the centroid c122 thereof when viewed in the third direction D3. Furthermore, the center c231 of the first resistance portion 1331 of the third magnetoresistance pattern portion 133 agrees with the centroid c131 thereof when viewed in the third direction D3 and the center c232 of the second resistance portion 1322 of the third magnetoresistance pattern portion 133 agrees with the centroid c132 thereof when viewed in the third direction D3. Furthermore, the center c241 of the first resistance portion 1341 of the fourth magnetoresistance pattern portion 134 agrees with the centroid c141 thereof when viewed in the third direction D3 and the center c242 of the second resistance portion 1342 of the fourth magnetoresistance pattern portion 134 agrees with the centroid c142 thereof when viewed in the third direction D3.

That is to say, in the magnetic sensor according to the first variation, the respective centroids c111, c112, c121, c122, c131, c132, c141, and c142 of the plurality of magnetoresistance pattern portions 131-134 are all located on the centerline L2 of the plurality of magnetoresistance pattern portions 131-134 in the second direction D2 when viewed in the third direction D3. More specifically, the centroid c111 of the first resistance portion 1311 of the first magnetoresistance pattern portion 131 and the centroid c112 of the second resistance portion 1312 of the first magnetoresistance pattern portion 131 are located on the centerline L2. Also, the centroid c121 of the first resistance portion 1321 of the second magnetoresistance pattern portion 132 and the centroid c122 of the second resistance portion 1322 of the second magnetoresistance pattern portion 132 are located on the centerline L2. Furthermore, the centroid c131 of the first resistance portion 1331 of the third magnetoresistance pattern portion 133 and the centroid c132 of the second resistance portion 1332 of the third magnetoresistance pattern portion 133 are located on the centerline L2. Furthermore, the centroid c141 of the first resistance portion 1341 of the fourth magnetoresistance pattern portion 134 and the centroid c142 of the second resistance portion 1342 of the fourth magnetoresistance pattern portion 134 are located on the centerline L2.

This reduces the dimension of the plurality of magnetoresistance pattern portions 131-134 in the second direction D2 compared to a situation where the respective centroids c111, c112, c121, c122, c131, c132, c141, and c142 of the plurality of magnetoresistance pattern portions 131-134 are shifted in the second direction D2 with respect to the centerline L2. Consequently, this contributes to downsizing the magnetic sensor 1 in the second direction D2. In addition, this may also reduce, even if the detection target 2 (refer to FIG. 3) tilts in the second direction D2 with respect to the magnetic sensor, for example, the variations in the resistance value of the magnetoresistance pattern portions 131-134 due to a dispersion in magnetic field strength distribution. Consequently, this enables reducing the position detection error of the detection target 2.

Furthermore, the magnetic sensor according to the first variation may also set the pattern width W3 of each magnetoresistance pattern portion 131-134 at a value equal to or greater than 15% and equal to or less than 25%, thus enabling reducing the position detection error of the detection target 2.

(5.2) Second Variation

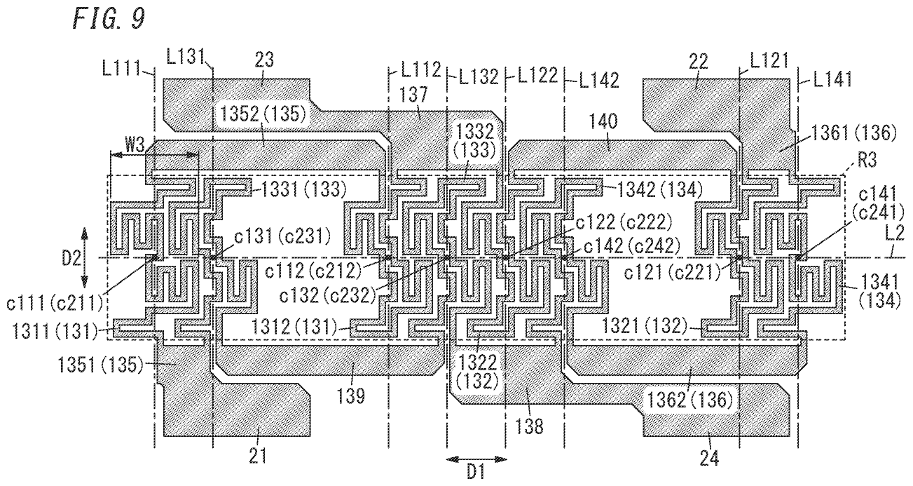

In a magnetic sensor according to a second variation, each resistance portion, located outside in the first direction D1, out of a plurality of resistance portions that form the plurality of magnetoresistance pattern portions 131-134 also serves as a wiring pattern portion that connects the first magnetoresistance pattern portion 131 and the power supply terminal 21 and as a wiring pattern portion that connects the fourth magnetoresistance pattern portion 134 and the ground terminal 22, which is a difference from the magnetic sensor according to the first variation described above. In the other respects, the magnetic sensor according to the second variation has the same configuration as the magnetic sensor according to the first variation described above. Thus, any constituent element of this second variation, having the same function as a counterpart of the first variation described above, will be designated by the same reference numeral as that counterpart's, and description thereof will be omitted herein. A magnetic sensor according to the second variation will now be described with reference to FIG. 9.

The magnetic sensor according to the second variation includes a plurality of (e.g., four) magnetoresistance pattern portions 131-134, first to sixth wiring pattern portions 135-140, and a plurality of (e.g., four) terminals 21-24 as shown in FIG. 9. The plurality of magnetoresistance pattern portions 131-134 consists of the first magnetoresistance pattern portion 131, the second magnetoresistance pattern portion 132, the third magnetoresistance pattern portion 133, and the fourth magnetoresistance pattern portion 134 as described above. The plurality of terminals 21-24 consists of the power supply terminal 21, the ground terminal 22, the first output terminal 23, and the second output terminal 24 as described above.

The first magnetoresistance pattern portion 131 includes a first resistance portion 1311 and a second resistance portion 1312. Each of the first resistance portion 1311 and the second resistance portion 1312 is formed in a meandering shape when viewed in the third direction D3 (i.e., the direction perpendicular to the paper sheet on which FIG. 9 is drawn). A first end portion of the first resistance portion 1311 is connected to the power supply terminal 21 via a first wiring portion 1351 of the first wiring pattern portion 135. A second end portion of the first resistance portion 1311 is connected to a second end portion of the second resistance portion 1312 via a second wiring portion 1352 of the first wiring pattern portion 135. A first end portion of the second resistance portion 1312 is connected to the first output terminal 23 via the third wiring pattern portion 137.

The second magnetoresistance pattern portion 132 includes a first resistance portion 1321 and a second resistance portion 1322. Each of the first resistance portion 1321 and the second resistance portion 1322 is formed in a meandering shape when viewed in the third direction D3. A first end portion of the first resistance portion 1321 is connected to the ground terminal 22 via a first wiring portion 1361 of the second wiring pattern portion 136. A second end portion of the first resistance portion 1321 is connected to a second end portion of the second resistance portion 1322 via a sixth wiring pattern portion 140. A first end portion of the second resistance portion 1322 is connected to the first output terminal 23 via the third wiring pattern portion 137.

The third magnetoresistance pattern portion 133 includes a first resistance portion 1331 and a second resistance portion 1332. Each of the first resistance portion 1331 and the second resistance portion 1332 is formed in a meandering shape when viewed in the third direction D3. A first end portion of the first resistance portion 1331 is connected to the power supply terminal 21 via a first wiring portion 1351 of the first wiring pattern portion 135. A second end portion of the first resistance portion 1331 is connected to a second end portion of the second resistance portion 1332 via the fifth wiring pattern portion 139. A first end portion of the second resistance portion 1332 is connected to the second output terminal 24 via the fourth wiring pattern portion 138.

The fourth magnetoresistance pattern portion 134 includes a first resistance portion 1341 and a second resistance portion 1342. Each of the first resistance portion 1341 and the second resistance portion 1342 is formed in a meandering shape when viewed in the third direction D3. A first end portion of the first resistance portion 1341 is connected to the ground terminal 22 via a first wiring portion 1361 of the second wiring pattern portion 136. A second end portion of the first resistance portion 1341 is connected to a second end portion of the second resistance portion 1342 via a second wiring portion 1362 of the second wiring pattern portion 136. A first end portion of the second resistance portion 1342 is connected to the second output terminal 24 via the fourth wiring pattern portion 138.

In the magnetic sensor according to the second variation, the first wiring portion 1351 and second wiring portion 1352 of the first wiring pattern portion 135 connected to the power supply terminal 21 are connected to each other via the first resistance portion 1311 as an outer resistance portion. In addition, in the magnetic sensor according to the second variation, the first wiring portion 1361 and second wiring portion 1362 of the second wiring pattern portion 136 connected to the ground terminal 22 are connected to each other via the first resistance portion 1341 as an outer resistance portion. As used herein, the “outer resistance portion” refers to a resistance portion, adjacent to another resistance portion on only one side in the first direction D1, out of the plurality of resistance portions arranged side by side in the first direction D1. Specifically, in the magnetic sensor according to the second variation, out of the plurality of resistance portions 1311, 1312, 1321, 1322, 1331, 1332, 1341, and 1342, the resistance portions 1311, 1341, located at both ends in the first direction D1, are outer resistance portions. The other resistance portions are inner resistance portions. As used herein, the “inner resistance portion” refers to a resistance portion, adjacent to other resistance portions on both sides in the first direction D1, out of the plurality of resistance portions arranged side by side in the first direction D1. Specifically, in the magnetic sensor according to the second variation, out of the plurality of resistance portions 1311, 1312, 1321, 1322, 1331, 1332, 1341, and 1342, the resistance portions 1312, 1321, 1322, 1331, 1332, and 1342, other than the resistance portions 1311, 1341 located at both ends on the first direction D1, are inner resistance portions. In addition, in the magnetic sensor according to the second variation, the first magnetoresistance pattern portion 131, the second magnetoresistance pattern portion 132, the third magnetoresistance pattern portion 133, and the fourth magnetoresistance pattern portion 134 are respective portions falling within the region R3 shown in FIG. 9.

In the magnetic sensor according to the second variation, the center c211 of the first resistance portion 1311 of the first magnetoresistance pattern portion 131 agrees with the centroid c111 thereof when viewed in the third direction D3 and the center c212 of the second resistance portion 1312 of the first magnetoresistance pattern portion 131 agrees with the centroid c112 thereof when viewed in the third direction D3. Also, the center c221 of the first resistance portion 1321 of the second magnetoresistance pattern portion 132 agrees with the centroid c121 thereof when viewed in the third direction D3 and the center c222 of the second resistance portion 1322 of the second magnetoresistance pattern portion 132 agrees with the centroid c122 thereof when viewed in the third direction D3. Furthermore, the center c231 of the first resistance portion 1331 of the third magnetoresistance pattern portion 133 agrees with the centroid c131 thereof when viewed in the third direction D3 and the center c232 of the second resistance portion 1332 of the third magnetoresistance pattern portion 133 agrees with the centroid c132 thereof when viewed in the third direction D3. Furthermore, the center c241 of the first resistance portion 1341 of the fourth magnetoresistance pattern portion 134 agrees with the centroid c141 thereof when viewed in the third direction D3 and the center c242 of the second resistance portion 1342 of the fourth magnetoresistance pattern portion 134 agrees with the centroid c142 thereof when viewed in the third direction D3.

That is to say, in the magnetic sensor according to the second variation, the respective centroids c111, c112, c121, c122, c131, c132, c141, and c142 of the plurality of magnetoresistance pattern portions 131-134 are all located on the centerline L2 of the plurality of magnetoresistance pattern portions 131-134 in the second direction D2 when viewed in the third direction D3. More specifically, the centroid c111 of the first resistance portion 1311 of the first magnetoresistance pattern portion 131 and the centroid c112 of the second resistance portion 1312 of the first magnetoresistance pattern portion 131 are located on the centerline L2. Also, the centroid c121 of the first resistance portion 1321 of the second magnetoresistance pattern portion 132 and the centroid c122 of the second resistance portion 1322 of the second magnetoresistance pattern portion 132 are located on the centerline L2. Furthermore, the centroid c131 of the first resistance portion 1331 of the third magnetoresistance pattern portion 133 and the centroid c132 of the second resistance portion 1332 of the third magnetoresistance pattern portion 133 are located on the centerline L2. Furthermore, the centroid c141 of the first resistance portion 1341 of the fourth magnetoresistance pattern portion 134 and the centroid c142 of the second resistance portion 1342 of the fourth magnetoresistance pattern portion 134 are located on the centerline L2.

This reduces the dimension of the plurality of magnetoresistance pattern portions 131-134 in the second direction D2 compared to a situation where the respective centroids c111, c112, c121, c122, c131, c132, c141, and c142 of the plurality of magnetoresistance pattern portions 131-134 are shifted in the second direction D2 with respect to the centerline L2. Consequently, this contributes to downsizing the magnetic sensor 1 in the second direction D2. In addition, this also reduces, even if the detection target 2 (refer to FIG. 3) tilts in the second direction D2 with respect to the magnetic sensor, for example, the variations in the resistance value of the magnetoresistance pattern portions 131-134 due to a dispersion in magnetic field strength distribution. Consequently, this enables reducing the position detection error of the detection target 2.

Furthermore, the magnetic sensor according to the first variation may also set the pattern width W3 of each magnetoresistance pattern portion 131-134 at a value equal to or greater than 15% and equal to or less than 25%, thus enabling reducing the position detection error of the detection target 2.

(5.3) Third Variation

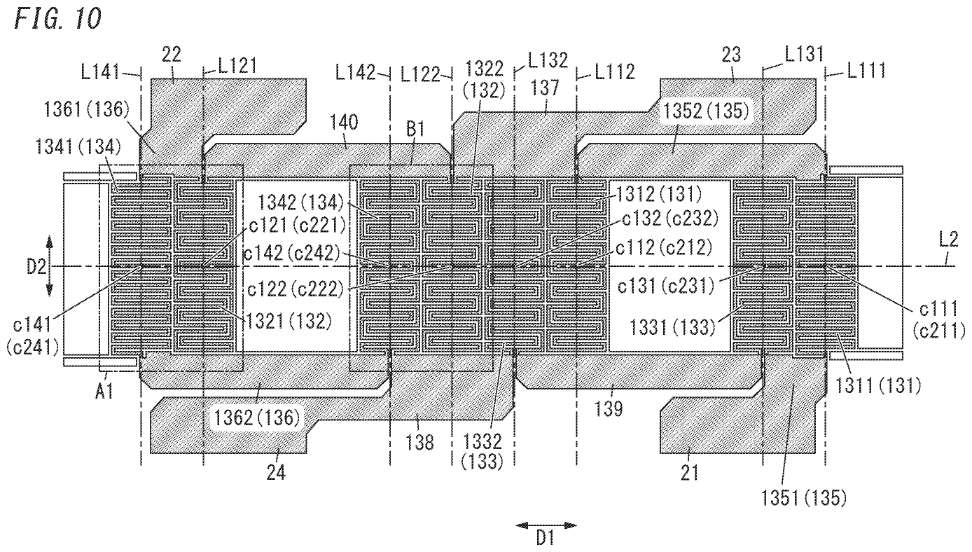

In a magnetic sensor according to a third variation, each magnetoresistance pattern portion 131-134 has a decreased line width, which is a difference from the magnetic sensor according to the second variation. In the other respects, the magnetic sensor according to the third variation has the same configuration as the magnetic sensor according to the second variation described above. Thus, any constituent element of this third variation, having the same function as a counterpart of the second variation described above, will be designated by the same reference numeral as that counterpart's, and description thereof will be omitted herein. A magnetic sensor according to the third variation will now be described with reference to FIGS. 10-12.

The magnetic sensor according to the third variation includes a plurality of (e.g., four) magnetoresistance pattern portions 131-134, first to sixth wiring pattern portions 135-140, and a plurality of (e.g., four) terminals 21-24 as shown in FIG. 10. The plurality of magnetoresistance pattern portions 131-134 consists of the first magnetoresistance pattern portion 131, the second magnetoresistance pattern portion 132, the third magnetoresistance pattern portion 133, and the fourth magnetoresistance pattern portion 134. The plurality of terminals 21-24 consists of the power supply terminal 21, the ground terminal 22, the first output terminal 23, and the second output terminal 24.

The first magnetoresistance pattern portion 131 includes a first resistance portion 1311 and a second resistance portion 1312. Each of the first resistance portion 1311 and the second resistance portion 1312 is formed in a meandering shape when viewed in the third direction D3 (i.e., the direction perpendicular to the paper sheet on which FIG. 10 is drawn). More specifically, the first resistance portion 1311 extends from one end in the second direction D2 (i.e., upper side in FIG. 10) toward the other end (i.e., lower side in FIG. 10) while meandering in a U-pattern in the first direction D1 when viewed in the third direction D3. Meanwhile, the second resistance portion 1312 extends from one end in the second direction D2 (i.e., upper side in FIG. 10) toward the other end (i.e., lower side in FIG. 10) while meandering in a U-pattern in the first direction D1 when viewed in the third direction D3. In addition, the second resistance portion 1312 also extends from the other end in the second direction D2 toward the one end in the second direction D2 while meandering in the first direction D1. Thus, both ends of the second resistance portion 1312 are located on the one end (i.e., upper side in FIG. 10) in the second direction D2. In addition, the second resistance portion 1312 is formed in the shape of comb teeth in which a first pattern portion extending from one end toward the other end in the second direction D2 and a second pattern portion extending from the other end toward the one end in the second direction D2 are alternately intertwined in the first direction D1. This allows the second resistance portion 1312 to have a decreased pattern width in the first direction D1. A first end portion of the first resistance portion 1311 is connected to the power supply terminal 21 via a first wiring portion 1351 of the first wiring pattern portion 135. A second end portion of the first resistance portion 1311 is connected to a second end portion of the second resistance portion 1312 via a second wiring portion 1352 of the first wiring pattern portion 135. A first end portion of the second resistance portion 1312 is connected to the first output terminal 23 via the third wiring pattern portion 137.

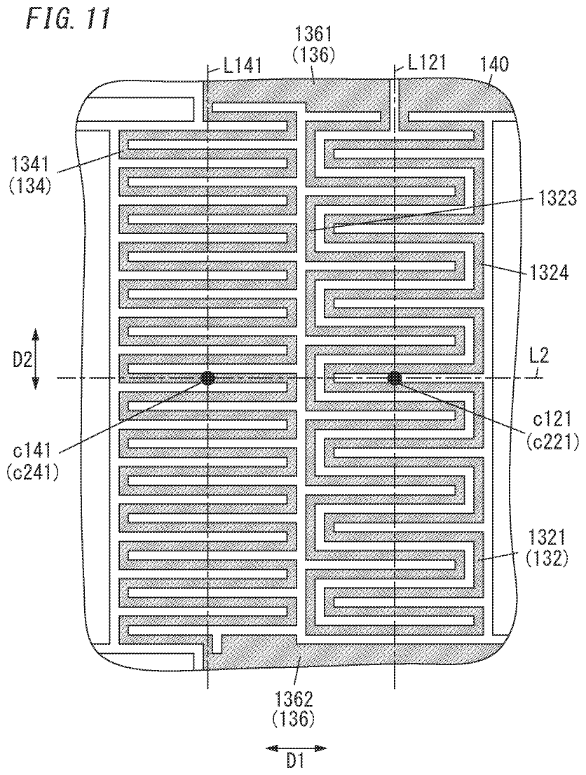

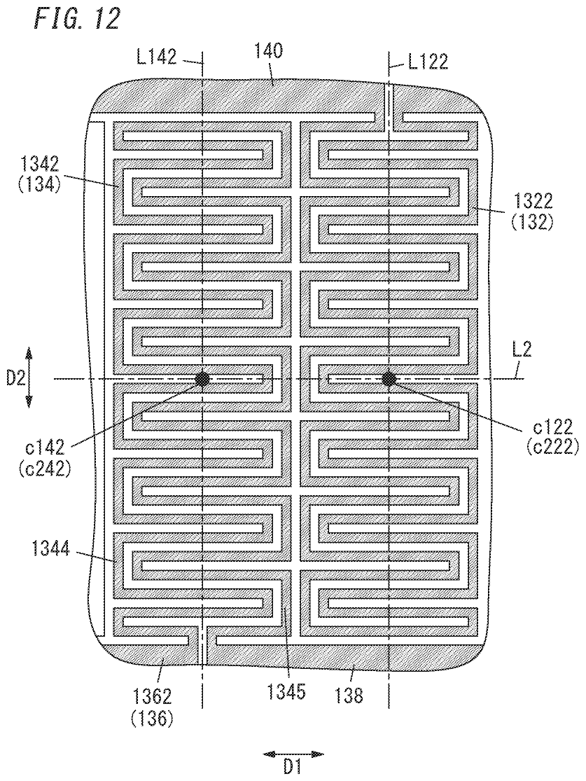

The second magnetoresistance pattern portion 132 includes a first resistance portion 1321 and a second resistance portion 1322. Each of the first resistance portion 1321 and the second resistance portion 1322 is formed in a meandering shape when viewed in the third direction D3 (i.e., the direction perpendicular to the paper sheet on which FIG. 10 is drawn). More specifically, each of the first resistance portion 1321 and the second resistance portion 1322 extends from one end in the second direction D2 (i.e., upper side in FIG. 10) toward the other end (i.e., lower side in FIG. 10) while meandering in a U-pattern in the first direction D1 when viewed in the third direction D3. In addition, each of the first resistance portion 1321 and the second resistance portion 1322 also extends from the other end in the second direction D2 toward the one end in the second direction D2 while meandering in the first direction D1 (refer to FIGS. 11 and 12). Thus, both ends of each of the first resistance portion 1321 and the second resistance portion 1322 are located on the one end (i.e., upper side in FIG. 10) in the second direction D2. In addition, each of the first resistance portion 1321 and the second resistance portion 1322 is formed in the shape of comb teeth in which a first pattern portion 1323 (refer to FIG. 11) extending from one end toward the other end in the second direction D2 and a second pattern portion 1324 (refer to FIG. 11) extending from the other end toward the one end in the second direction D2 are alternately intertwined in the first direction D1. This allows the first resistance portion 1321 and the second resistance portion 1322 to have a decreased pattern width in the first direction D1. A first end portion of the first resistance portion 1321 is connected to the ground terminal 22 via a first wiring portion 1361 of the second wiring pattern portion 136. A second end portion of the first resistance portion 1321 is connected to a second end portion of the second resistance portion 1322 via the sixth wiring pattern portion 140. A first end portion of the second resistance portion 1322 is connected to the first output terminal 23 via the third wiring pattern portion 137.

The third magnetoresistance pattern portion 133 includes a first resistance portion 1331 and a second resistance portion 1332. Each of the first resistance portion 1331 and the second resistance portion 1332 is formed in a meandering shape when viewed in the third direction D3 (i.e., the direction perpendicular to the paper sheet on which FIG. 10 is drawn). More specifically, each of the first resistance portion 1331 and the second resistance portion 1332 extends from one end in the second direction D2 (i.e., lower side in FIG. 10) toward the other end (i.e., upper side in FIG. 10) while meandering in a U-pattern in the first direction D1 when viewed in the third direction D3. In addition, each of the first resistance portion 1331 and the second resistance portion 1332 also extends from the other end in the second direction D2 toward the one end in the second direction D2 while meandering in the first direction D1. Thus, both ends of each of the first resistance portion 1331 and the second resistance portion 1332 are located on the one end (i.e., lower side in FIG. 10) in the second direction D2. In addition, each of the first resistance portion 1331 and the second resistance portion 1332 is formed in the shape of comb teeth in which a first pattern portion extending from one end toward the other end in the second direction D2 and a second pattern portion extending from the other end toward the one end in the second direction D2 are alternately intertwined in the first direction D1. This allows the first resistance portion 1331 and the second resistance portion 1332 to have a decreased pattern width in the first direction D1. A first end portion of the first resistance portion 1331 is connected to the power supply terminal 21 via a first wiring portion 1351 of the first wiring pattern portion 135. A second end portion of the first resistance portion 1331 is connected to a second end portion of the second resistance portion 1332 via the fifth wiring pattern portion 139. A first end portion of the second resistance portion 1332 is connected to the second output terminal 24 via the fourth wiring pattern portion 138.

The fourth magnetoresistance pattern portion 134 includes a first resistance portion 1341 and a second resistance portion 1342. Each of the first resistance portion 1341 and the second resistance portion 1342 is formed in a meandering shape when viewed in the third direction D3 (i.e., the direction perpendicular to the paper sheet on which FIG. 10 is drawn). More specifically, the first resistance portion 1341 extends from one end in the second direction D2 (i.e., upper side in FIG. 10) toward the other end (i.e., lower side in FIG. 10) while meandering in a U-pattern in the first direction D1 when viewed in the third direction D3. The second resistance portion 1342 extends from the other end in the second direction D2 (i.e., lower side in FIG. 10) toward the one end (i.e., upper side in FIG. 10) while meandering in a U-pattern in the first direction D1 when viewed in the third direction D3. In addition, the second resistance portion 1342 also extends from the one end in the second direction D2 toward the other end in the second direction D2 while meandering in the first direction D1 (refer to FIG. 12). Thus, both ends of each of the second resistance portion 1342 are located on the other end (i.e., lower side in FIG. 10) in the second direction D2. In addition, the second resistance portion 1342 is formed in the shape of comb teeth in which a first pattern portion 1344 (refer to FIG. 12) extending from the other end toward the one end in the second direction D2 and a second pattern portion 1345 (refer to FIG. 12) extending from the one end toward the other end in the second direction D2 are alternately intertwined in the first direction D1. This allows the second resistance portion 1342 to have a decreased pattern width in the first direction D1. A first end portion of the first resistance portion 1341 is connected to the ground terminal 22 via a first wiring portion 1361 of the second wiring pattern portion 136. A second end portion of the first resistance portion 1341 is connected to a second end portion of the second resistance portion 1342 via a second wiring portion 1362 of the second wiring pattern portion 136. A first end portion of the second resistance portion 1342 is connected to the second output terminal 24 via the fourth wiring pattern portion 138.

In the magnetic sensor according to the third variation, the center c211 of the first resistance portion 1311 of the first magnetoresistance pattern portion 131 agrees with the centroid c111 thereof when viewed in the third direction D3 and the center c212 of the second resistance portion 1312 of the first magnetoresistance pattern portion 131 agrees with the centroid c112 thereof when viewed in the third direction D3. Also, the center c221 of the first resistance portion 1321 of the second magnetoresistance pattern portion 132 agrees with the centroid c121 thereof when viewed in the third direction D3 and the center c222 of the second resistance portion 1322 of the second magnetoresistance pattern portion 132 agrees with the centroid c122 thereof when viewed in the third direction D3. Furthermore, the center c231 of the first resistance portion 1331 of the third magnetoresistance pattern portion 133 agrees with the centroid c131 thereof when viewed in the third direction D3 and the center c232 of the second resistance portion 1332 of the third magnetoresistance pattern portion 133 agrees with the centroid c132 thereof when viewed in the third direction D3. Furthermore, the center c241 of the first resistance portion 1341 of the fourth magnetoresistance pattern portion 134 agrees with the centroid c141 thereof when viewed in the third direction D3 and the center c242 of the second resistance portion 1342 of the fourth magnetoresistance pattern portion 134 agrees with the centroid c142 thereof when viewed in the third direction D3.

That is to say, in the magnetic sensor according to the third variation, the respective centroids c111, c112, c121, c122, c131, c132, c141, and c142 of the plurality of magnetoresistance pattern portions 131-134 are all located on the centerline L2 of the plurality of magnetoresistance pattern portions 131-134 in the second direction D2 when viewed in the third direction D3. More specifically, the centroid c111 of the first resistance portion 1311 of the first magnetoresistance pattern portion 131 and the centroid c112 of the second resistance portion 1312 of the first magnetoresistance pattern portion 131 are located on the centerline L2. Also, the centroid c121 of the first resistance portion 1321 of the second magnetoresistance pattern portion 132 and the centroid c122 of the second resistance portion 1322 of the second magnetoresistance pattern portion 132 are located on the centerline L2. Furthermore, the centroid c131 of the first resistance portion 1331 of the third magnetoresistance pattern portion 133 and the centroid c132 of the second resistance portion 1332 of the third magnetoresistance pattern portion 133 are located on the centerline L2. Furthermore, the centroid c141 of the first resistance portion 1341 of the fourth magnetoresistance pattern portion 134 and the centroid c142 of the second resistance portion 1342 of the fourth magnetoresistance pattern portion 134 are located on the centerline L2.

This reduces the dimension of the plurality of magnetoresistance pattern portions 131-134 in the second direction D2 compared to a situation where the respective centroids c111, c112, c121, c122, c131, c132, c141, and c142 of the plurality of magnetoresistance pattern portions 131-134 are shifted in the second direction D2 with respect to the centerline L2. Consequently, this contributes to downsizing the magnetic sensor 1 in the second direction D2. In addition, this also reduces, even if the detection target 2 (refer to FIG. 3) tilts in the second direction D2 with respect to the magnetic sensor, for example, the variations in the resistance value of the magnetoresistance pattern portions 131-134 due to a dispersion in magnetic field strength distribution. Consequently, this enables reducing the position detection error of the detection target 2.

In this case, in the magnetic sensor according to the second variation shown in FIG. 9 and the magnetic sensor according to the third variation, as well as the magnetic sensor 1 according to the first embodiment and the magnetic sensor according to the first variation described above, each of the magnetoresistance pattern portions 131-134 is configured as, for example, an artificial lattice film in which magnetic layers, each containing an NiFeCo alloy, and non-magnetic layers, each containing a Cu alloy, are alternately stacked one on top of another.

Also, in the magnetic sensor according to the second variation shown in FIG. 9, each magnetoresistance pattern portion 131-134 may have a line width equal to or greater than 10 μm and equal to or less than 30 μm, for example. In the magnetic sensor according to the second variation, a bridge circuit formed by these magnetoresistance pattern portions 131-134 may have a resistance value equal to or greater than 1 kΩ and equal to or less than 5 kΩ, for example.

In contrast, in the magnetic sensor according to the third variation, each magnetoresistance pattern portion 131-134 may have a line width equal to or greater than 5 μm and equal to or less than 15 μm, for example. In addition, the line width of each magnetoresistance pattern portion 131-134 of the magnetic sensor according to the third variation is one half as long as the line width of each magnetoresistance pattern portion 131-134 of the magnetic sensor according to the second variation. Thus, if the line width of each magnetoresistance pattern portion 131-134 of the magnetic sensor according to the second variation is 10 μm, then the line width of each magnetoresistance pattern portion 131-134 of the magnetic sensor according to the third variation is 5 μm. In addition, in the magnetic sensor according to the third variation, a bridge circuit formed by the respective magnetoresistance pattern portions 131-134 may have a resistance value equal to or greater than 5 kΩ and equal to or less than 10 kΩ, for example.

Decreasing the line width of each magnetoresistance pattern portion 131-134 as much as in the magnetic sensor according to the third variation enables increasing the resistance values of the plurality of magnetoresistance pattern portions 131-134. This may cut down power consumption required to deliver desired signal output. That is to say, the magnetic sensor according to the third variation enables increasing signal output per power consumption.

(5.4) Fourth Variation

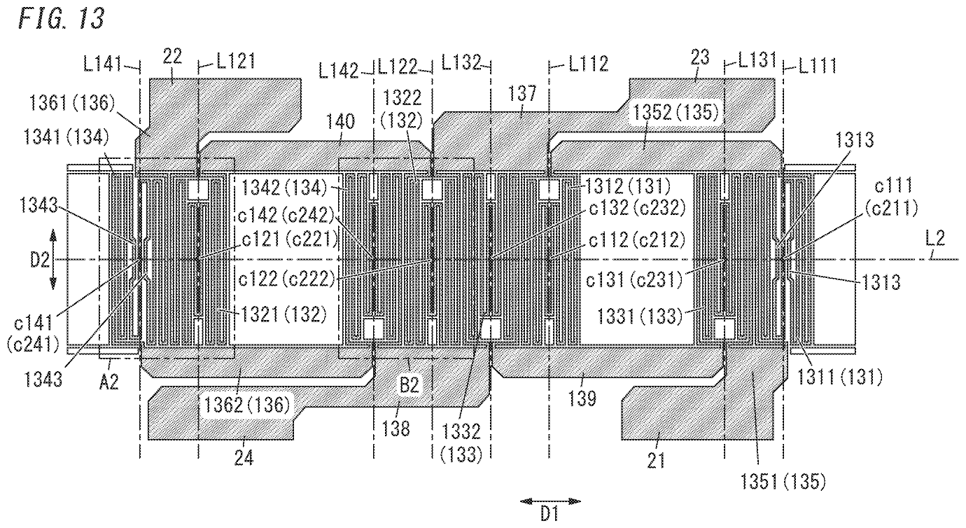

In a magnetic sensor according to a fourth variation, each magnetoresistance pattern portion 131-134 is formed to extend in the second direction D2, which is a difference from the magnetic sensor according to the third variation. In the other respects, the magnetic sensor according to the fourth variation has the same configuration as the magnetic sensor according to the third variation described above. Thus, any constituent element of this fourth variation, having the same function as a counterpart of the third variation described above, will be designated by the same reference numeral as that counterpart's, and description thereof will be omitted herein. A magnetic sensor according to the fourth variation will now be described with reference to FIGS. 13-15.

The magnetic sensor according to the fourth variation includes a plurality of (e.g., four) magnetoresistance pattern portions 131-134, first to sixth wiring pattern portions 135-140, and a plurality of (e.g., four) terminals 21-24 as shown in FIG. 13. The plurality of magnetoresistance pattern portions 131-134 consists of the first magnetoresistance pattern portion 131, the second magnetoresistance pattern portion 132, the third magnetoresistance pattern portion 133, and the fourth magnetoresistance pattern portion 134. The plurality of terminals 21-24 consists of the power supply terminal 21, the ground terminal 22, the first output terminal 23, and the second output terminal 24.

The first magnetoresistance pattern portion 131 includes a first resistance portion 1311 and a second resistance portion 1312. Each of the first resistance portion 1311 and the second resistance portion 1312 is formed in a meandering shape when viewed in the third direction D3 (i.e., the direction perpendicular to the paper sheet on which FIG. 13 is drawn). More specifically, each of the first resistance portion 1311 and the second resistance portion 1312 extends from one end in the first direction D1 (i.e., left side in FIG. 13) toward the other end (i.e., right side in FIG. 13) while meandering in a U-pattern in the second direction D2 when viewed in the third direction D3. In addition, the first resistance portion 1311 includes a pair of bulging portions 1313, 1313 as shown in FIG. 13. The pair of bulging portions 1313, 1313 each have a rectangular shape and bulge toward each other in a central part of the first resistance portion 1311 in the first direction D1. Furthermore, the first resistance portion 1311 has a shape which is symmetric with respect to the center c211 as its point of symmetry (i.e., center of symmetry). On the other hand, the second resistance portion 1312 has a shape which is symmetric with respect to a centerline L112 (axis of symmetry) aligned with the second direction D2. A first end portion of the first resistance portion 1311 is connected to the power supply terminal 21 via a first wiring portion 1351 of the first wiring pattern portion 135. A second end portion of the first resistance portion 1311 is connected to a second end portion of the second resistance portion 1312 via a second wiring portion 1352 of the first wiring pattern portion 135. A first end portion of the second resistance portion 1312 is connected to the first output terminal 23 via the third wiring pattern portion 137.

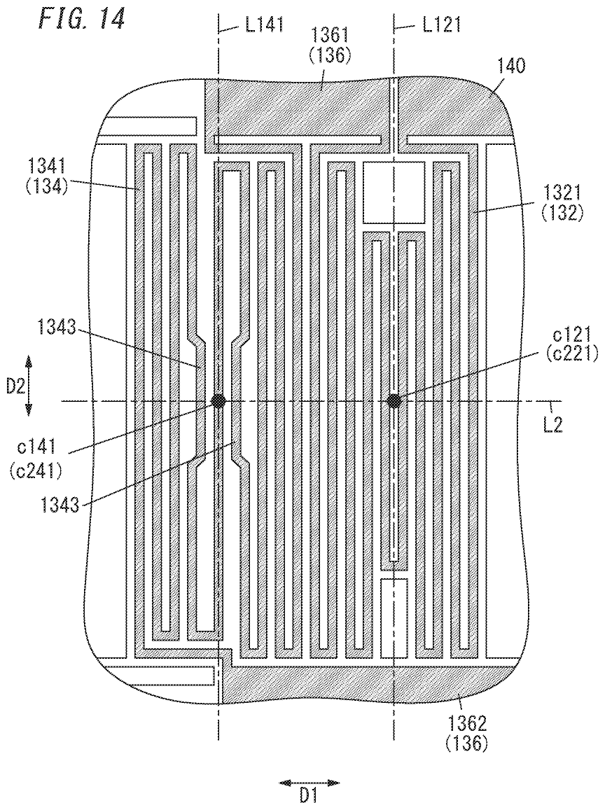

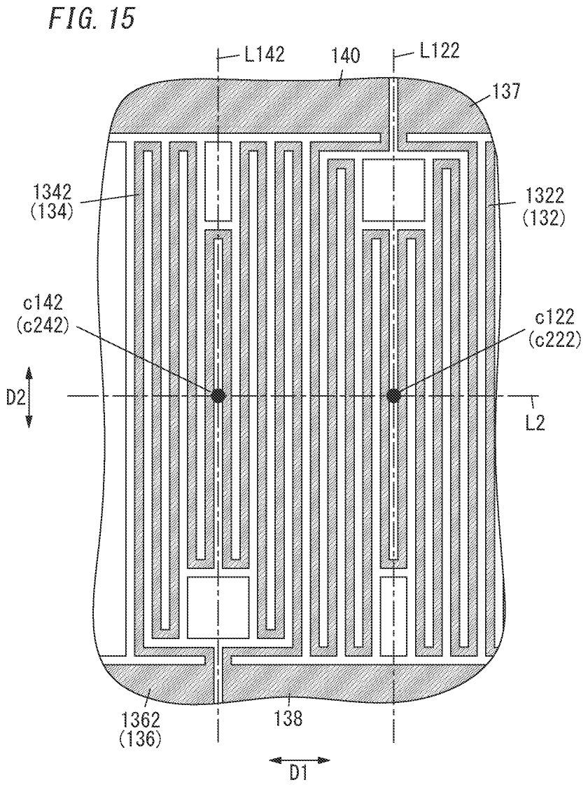

The second magnetoresistance pattern portion 132 includes a first resistance portion 1321 and a second resistance portion 1322. Each of the first resistance portion 1321 and the second resistance portion 1322 is formed in a meandering shape when viewed in the third direction D3 (i.e., the direction perpendicular to the paper sheet on which FIG. 13 is drawn). More specifically, each of the first resistance portion 1321 and the second resistance portion 1322 extends from one end in the first direction D1 (i.e., left side in FIG. 13) toward the other end (i.e., right side in FIG. 13) while meandering in a U-pattern in the second direction D2 when viewed in the third direction D3. The first resistance portion 1321 has a shape which is symmetric with respect to the centerline L121 (axis of symmetry) aligned with the second direction D2 as shown in FIG. 14. On the other hand, the second resistance portion 1322 has a shape which is symmetric with respect to a centerline L122 (axis of symmetry) aligned with the second direction D2 as shown in FIG. 15. A first end portion of the first resistance portion 1321 is connected to the ground terminal 22 via a first wiring portion 1361 of the second wiring pattern portion 136. A second end portion of the first resistance portion 1321 is connected to a second end portion of the second resistance portion 1322 via the sixth wiring pattern portion 140. A first end portion of the second resistance portion 1322 is connected to the first output terminal 23 via the third wiring pattern portion 137.

The third magnetoresistance pattern portion 133 includes a first resistance portion 1331 and a second resistance portion 1332. Each of the first resistance portion 1331 and the second resistance portion 1332 is formed in a meandering shape when viewed in the third direction D3 (i.e., the direction perpendicular to the paper sheet on which FIG. 13 is drawn). More specifically, each of the first resistance portion 1331 and the second resistance portion 1332 extends from one end in the first direction D1 (i.e., left side in FIG. 13) toward the other end (i.e., right side in FIG. 13) while meandering in a U-pattern in the second direction D2 when viewed in the third direction D3. The first resistance portion 1331 has a shape which is symmetric with respect to a centerline L111 (axis of symmetry) aligned with the second direction D2. On the other hand, the second resistance portion 1332 has a shape which is symmetric with respect to a centerline L132 (axis of symmetry) aligned with the second direction D2. A first end portion of the first resistance portion 1331 is connected to the power supply terminal 21 via a first wiring portion 1351 of the first wiring pattern portion 135. A second end portion of the first resistance portion 1331 is connected to a second end portion of the second resistance portion 1332 via the fifth wiring pattern portion 139. A first end portion of the second resistance portion 1332 is connected to the second output terminal 24 via the fourth wiring pattern portion 138.

The fourth magnetoresistance pattern portion 134 includes a first resistance portion 1341 and a second resistance portion 1342. Each of the first resistance portion 1341 and the second resistance portion 1342 is formed in a meandering shape when viewed in the third direction D3 (i.e., the direction perpendicular to the paper sheet on which FIG. 13 is drawn). More specifically, each of the first resistance portion 1341 and the second resistance portion 1342 extends from one end in the first direction D1 (i.e., right side in FIG. 13) toward the other end (i.e., left side in FIG. 13) while meandering in a U-pattern in the second direction D2 when viewed in the third direction D3. In addition, the first resistance portion 1341 includes a pair of bulging portions 1343, 1343 as shown in FIG. 14. The pair of bulging portions 1343, 1343 each have a rectangular shape and bulge toward each other in a central part of the first resistance portion 1341 in the first direction D1. Furthermore, the first resistance portion 1341 has a shape which is symmetric with respect to the center c241 as its point of symmetry (i.e., center of symmetry). On the other hand, the second resistance portion 1342 has a shape which is symmetric with respect to a centerline L142 (axis of symmetry) aligned with the second direction D2 as shown in FIG. 15. A first end portion of the first resistance portion 1341 is connected to the ground terminal 22 via a first wiring portion 1361 of the second wiring pattern portion 136. A second end portion of the first resistance portion 1341 is connected to a second end portion of the second resistance portion 1342 via a second wiring portion 1362 of the second wiring pattern portion 136. A first end portion of the second resistance portion 1342 is connected to the second output terminal 24 via the fourth wiring pattern portion 138.

In the magnetic sensor according to the fourth variation, the center c211 of the first resistance portion 1311 of the first magnetoresistance pattern portion 131 agrees with the centroid c111 thereof when viewed in the third direction D3 and the center c212 of the second resistance portion 1312 of the first magnetoresistance pattern portion 131 agrees with the centroid c112 thereof when viewed in the third direction D3. Also, the center c221 of the first resistance portion 1321 of the second magnetoresistance pattern portion 132 agrees with the centroid c121 thereof when viewed in the third direction D3 and the center c222 of the second resistance portion 1322 of the second magnetoresistance pattern portion 132 agrees with the centroid c122 thereof when viewed in the third direction D3. Furthermore, the center c231 of the first resistance portion 1331 of the third magnetoresistance pattern portion 133 agrees with the centroid c131 thereof when viewed in the third direction D3 and the center c232 of the second resistance portion 1332 of the third magnetoresistance pattern portion 133 agrees with the centroid c132 thereof when viewed in the third direction D3. Furthermore, the center c241 of the first resistance portion 1341 of the fourth magnetoresistance pattern portion 134 agrees with the centroid c141 thereof when viewed in the third direction D3 and the center c242 of the second resistance portion 1342 of the fourth magnetoresistance pattern portion 134 agrees with the centroid c142 thereof when viewed in the third direction D3.

That is to say, in the magnetic sensor according to the fourth variation, the respective centroids c111, c112, c121, c122, c131, c132, c141, and c142 of the plurality of magnetoresistance pattern portions 131-134 are all located on the centerline L2 of the plurality of magnetoresistance pattern portions 131-134 in the second direction D2 when viewed in the third direction D3. More specifically, the centroid c111 of the first resistance portion 1311 of the first magnetoresistance pattern portion 131 and the centroid c112 of the second resistance portion 1312 of the first magnetoresistance pattern portion 131 are located on the centerline L2. Also, the centroid c121 of the first resistance portion 1321 of the second magnetoresistance pattern portion 132 and the centroid c122 of the second resistance portion 1322 of the second magnetoresistance pattern portion 132 are located on the centerline L2. Furthermore, the centroid c131 of the first resistance portion 1331 of the third magnetoresistance pattern portion 133 and the centroid c132 of the second resistance portion 1332 of the third magnetoresistance pattern portion 133 are located on the centerline L2. Furthermore, the centroid c141 of the first resistance portion 1341 of the fourth magnetoresistance pattern portion 134 and the centroid c142 of the second resistance portion 1342 of the fourth magnetoresistance pattern portion 134 are located on the centerline L2.

This reduces the dimension of the plurality of magnetoresistance pattern portions 131-134 in the second direction D2 compared to a situation where the respective centroids c111, c112, c121, c122, c131, c132, c141, and c142 of the plurality of magnetoresistance pattern portions 131-134 are shifted in the second direction D2 with respect to the centerline L2. Consequently, this contributes to downsizing the magnetic sensor 1 in the second direction D2. In addition, this also reduces, even if the detection target 2 (refer to FIG. 3) tilts in the second direction D2 with respect to the magnetic sensor, for example, the variations in the resistance value of the magnetoresistance pattern portions 131-134 due to a dispersion in magnetic field strength distribution. Consequently, this enables reducing the position detection error of the detection target 2.

In addition, in the magnetic sensor according to the fourth variation, each magnetoresistance pattern portion 131-134 has a narrower line width than its corresponding magnetoresistance pattern portion 131-134 of the magnetic sensor according to the second variation. This enables increasing the resistance value of a bridge circuit formed by these magnetoresistance pattern portions 131-134 and thereby cutting down power consumption required to deliver desired signal output.

(5.5) Other Variations

Next, other variations of the first embodiment will be enumerated one after another.

Each of the plurality of magnetoresistance pattern portions 131-134 does not have to have the meandering shape but may also have any other suitable shape.

In the first embodiment and the first, second, third, and fourth variations described above, each magnetoresistance pattern portion 131-134 is made up of either one resistance portion or two resistance portions. Alternatively, each magnetoresistance pattern portion 131-134 may also be made up of three or more resistance portions, for example.

### Second Embodiment

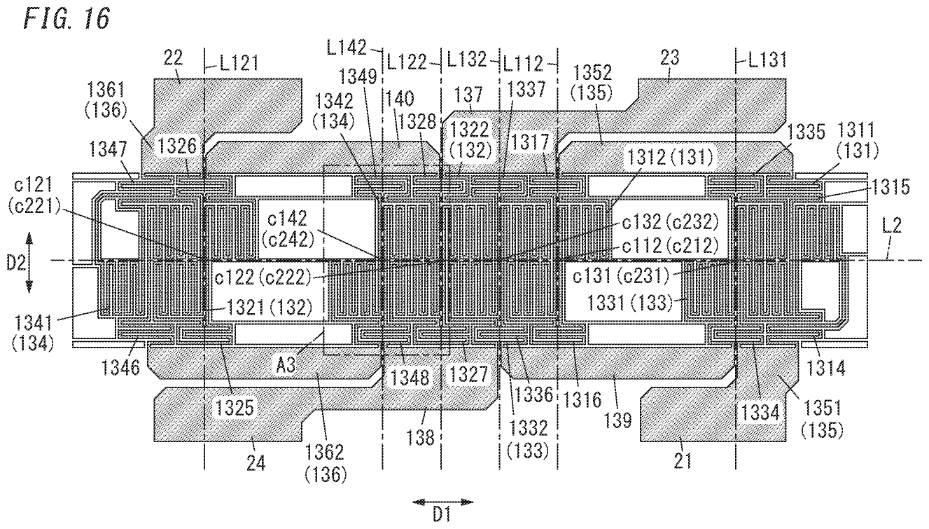

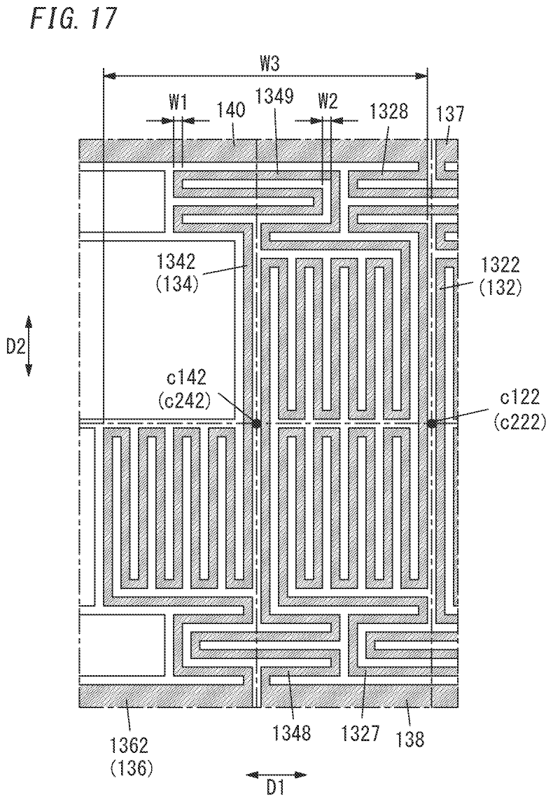

A magnetic sensor according to a second embodiment will be described with reference to FIGS. 16 and 17. In the following description, any constituent element of the magnetic sensor according to this second embodiment, having the same function as a counterpart of the magnetic sensor 1 according to the first embodiment described above, will be designated by the same reference numeral as that counterpart's, and description thereof will be omitted herein.

In the magnetic sensor according to the second embodiment, each of the plurality of magnetoresistance pattern portions 131-134 is made up of plurality of resistance portions, which is a difference from the magnetic sensor 1 according to the first embodiment. In addition, in the magnetic sensor according to the second embodiment, each magnetoresistance pattern portion 131-134 has a narrower line width, which is another difference from the magnetic sensor 1 according to the first embodiment.

(1) Overview

Patent Literature 1 cited above discloses a magnetoresistive element (magnetic sensor) including an insulating substrate (supporting substrate) and a magnetoresistive film provided on the insulating substrate. The magnetoresistive film includes a plurality of double meandering magneto-sensitive pattern units (magnetoresistance pattern portions). The plurality of double meandering magneto-sensitive pattern units are arranged side by side in the direction in which a magnet moves with respect to the magnetoresistive element.

The magnetoresistive element of Patent Literature 1 cited above may certainly reduce an error to be caused by waveform distortion but tends to have an increased size, which is a problem with the magnetoresistive element of Patent Literature 1. To overcome this problem, a magnetic sensor according to the second embodiment adopts the following configuration.

Specifically, a magnetic sensor according to the second embodiment is configured to detect the position of a detection target 2 (refer to FIG. 3) based on a change in magnetic field strength to be caused by relative movement of the detection target 2 in the first direction D1. The detection target 2 is magnetized in the first direction D1 in a predetermined cycle of magnetization λ (refer to FIG. 3). The magnetic sensor includes a plurality of magnetoresistance pattern portions 131-134. The plurality of magnetoresistance pattern portions 131-134 forms a bridge circuit. The plurality of magnetoresistance pattern portions 131-134 are arranged side by side in the first direction D1. Each of the plurality of magnetoresistance pattern portions 131-134 is formed in a second direction D2 perpendicular to the first direction D1. Each of the plurality of magnetoresistance pattern portions 131-134 has a pattern width W3 (refer to FIG. 5) that is equal to or greater than 15% and equal to or less than 25% of the cycle of magnetization λ. Each of the plurality of magnetoresistance pattern portions 131-134 is formed in a meandering shape when viewed in a third direction D3. The third direction D3 is perpendicular to both the first direction D1 and the second direction D2. Each of the plurality of magnetoresistance pattern portions 131-134 is adjacent, in the first direction D1, to a neighboring magnetoresistance pattern portion and includes a part protruding in the first direction D1 toward the neighboring magnetoresistance pattern portion to overlap, in the second direction D2, with a part of the neighboring magnetoresistance pattern portion.

In the magnetic sensor according to the second embodiment, the pattern width W3 of each of the plurality of magnetoresistance pattern portions 131-134 is equal to or greater than 15% of the cycle of magnetization λ of the detection target 2. This makes the reaction of the detection target 2 to a change in flux density due to its relative movement much less steep than in a situation where the pattern width W3 of each of the plurality of magnetoresistance pattern portions 131-134 is less than 15% of the cycle of magnetization λ of the detection target 2. Consequently, this reduces the error to be caused by waveform distortion. In addition, in the magnetic sensor according to the second embodiment, each of the plurality of magnetoresistance pattern portions 131-134 is adjacent, in the first direction D1, to a neighboring magnetoresistance pattern portion and includes a part protruding in the first direction D1 toward the neighboring magnetoresistance pattern portion to overlap, in the second direction D2, with a part of the neighboring magnetoresistance pattern portion. This shortens the gap distance between adjacent ones of the magnetoresistance pattern portions 131-134, thus contributing to downsizing the magnetic sensor 1. That is to say, the magnetic sensor according to the second embodiment contributes to downsizing while reducing the error to be caused by waveform distortion.

Furthermore, if the pattern width W3 of each of the plurality of magnetoresistance pattern portions 131-134 were greater than 25% of the cycle of magnetization λ of the detection target 2, then two adjacent magnetoresistance pattern portions would react simultaneously to the same magnetic pole of the detection target 2, thus possibly causing a decline in the positioning accuracy of the detection target 2. In contrast, in the magnetic sensor according to the second embodiment, the pattern width W3 of each of the plurality of magnetoresistance pattern portions 131-134 is equal to or less than 25% of the cycle of magnetization λ of the detection target 2. This significantly reduces the chances of two adjacent magnetoresistance pattern portions reacting simultaneously to the same magnetic pole of the detection target 2, thus reducing the chances of causing a decline in the positioning accuracy of the detection target 2.

(2) Details

The magnetic sensor according to the second embodiment includes a plurality of (e.g., four) magnetoresistance pattern portions 131-134, first to sixth wiring pattern portions 135-140, and a plurality of (e.g., four) terminals 21-24 as shown in FIG. 16. The plurality of magnetoresistance pattern portions 131-134 consists of the first magnetoresistance pattern portion 131, the second magnetoresistance pattern portion 132, the third magnetoresistance pattern portion 133, and the fourth magnetoresistance pattern portion 134. The plurality of terminals 21-24 consists of the power supply terminal 21, the ground terminal 22, the first output terminal 23, and the second output terminal 24.

The first magnetoresistance pattern portion 131 includes a first resistance portion 1311 and a second resistance portion 1312. Each of the first resistance portion 1311 and the second resistance portion 1312 is formed in a meandering shape when viewed in the third direction D3 (i.e., the direction perpendicular to the paper sheet on which FIG. 16 is drawn). The first resistance portion 1311 includes a first part 1314 and a second part 1315. The first part 1314 meanders in a U-pattern in the first direction D1 in a region under a centerline L2 and also meanders in a U-pattern in the second direction D2 in a region over the centerline L2. The second part 1315 meanders in a U-pattern in the first direction D1 in a region over the centerline L2 and also meanders in a U-pattern in the second direction D2 in a region under the centerline L2. The second resistance portion 1312 includes a first part 1316 and a second part 1317. The first part 1316 meanders in a U-pattern in the first direction D1 in a region under the centerline L2 and also meanders in a U-pattern in the second direction D2 in a region over the centerline L2. The second part 1317 meanders in a U-pattern in the first direction D1 in a region over the centerline L2 and also meanders in a U-pattern in the second direction D2 in a region under the centerline L2. In addition, in the second resistance portion 1312, the first part 1316 and the second part 1317 have shapes which are symmetric to each other with respect to the center c212 of the second resistance portion 1312 as its point of symmetry (i.e., the center of symmetry). A first end portion of the first resistance portion 1311 is connected to the power supply terminal 21 via a first wiring portion 1351 of the first wiring pattern portion 135. A second end portion of the first resistance portion 1311 is connected to a second end portion of the second resistance portion 1312 via a second wiring portion 1352 of the first wiring pattern portion 135. A first end portion of the second resistance portion 1312 is connected to the first output terminal 23 via the third wiring pattern portion 137.

The second magnetoresistance pattern portion 132 includes a first resistance portion 1321 and a second resistance portion 1322. Each of the first resistance portion 1321 and the second resistance portion 1322 is formed in a meandering shape when viewed in the third direction D3 (i.e., the direction perpendicular to the paper sheet on which FIG. 16 is drawn). The first resistance portion 1321 includes a first part 1325 and a second part 1326. The first part 1325 meanders in a U-pattern in the first direction D1 in a region under the centerline L2 and also meanders in a U-pattern in the second direction D2 in a region over the centerline L2. The second part 1326 meanders in a U-pattern in the first direction D1 in a region over the centerline L2 and also meanders in a U-pattern in the second direction D2 in a region under the centerline L2. In addition, in the first resistance portion 1321, the first part 1325 and the second part 1326 have shapes which are symmetric to each other with respect to the center c221 of the first resistance portion 1321 as its point of symmetry (i.e., the center of symmetry). The second resistance portion 1322 includes a first part 1327 and a second part 1328. The first part 1327 meanders in a U-pattern in the first direction D1 in a region under the centerline L2 and also meanders in a U-pattern in the second direction D2 in a region over the centerline L2. The second part 1328 meanders in a U-pattern in the first direction D1 in a region over the centerline L2 and also meanders in a U-pattern in the second direction D2 in a region under the centerline L2. In addition, in the second resistance portion 1322, the first part 1327 and the second part 1328 have shapes which are symmetric to each other with respect to the center c222 of the second resistance portion 1322 as its point of symmetry (i.e., the center of symmetry). A first end portion of the first resistance portion 1321 is connected to the ground terminal 22 via a first wiring portion 1361 of the second wiring pattern portion 136. A second end portion of the first resistance portion 1321 is connected to a second end portion of the second resistance portion 1322 via the sixth wiring pattern portion 140. A first end portion of the second resistance portion 1322 is connected to the first output terminal 23 via the third wiring pattern portion 137.

The third magnetoresistance pattern portion 133 includes a first resistance portion 1331 and a second resistance portion 1332. Each of the first resistance portion 1331 and the second resistance portion 1332 is formed in a meandering shape when viewed in the third direction D3 (i.e., the direction perpendicular to the paper sheet on which FIG. 16 is drawn). The first resistance portion 1331 includes a first part 1334 and a second part 1335. The first part 1334 meanders in a U-pattern in the first direction D1 in a region under the centerline L2 and also meanders in a U-pattern in the second direction D2 in a region over the centerline L2. The second part 1335 meanders in a U-pattern in the first direction D1 in a region over the centerline L2 and also meanders in a U-pattern in the second direction D2 in a region under the centerline L2. In addition, in the first resistance portion 1331, the first part 1334 and the second part 1335 have shapes which are symmetric to each other with respect to the center c231 of the first resistance portion 1331 as its point of symmetry (i.e., the center of symmetry). The second resistance portion 1332 includes a first part 1336 and a second part 1337. The first part 1336 meanders in a U-pattern in the first direction D1 in a region under the centerline L2 and also meanders in a U-pattern in the second direction D2 in a region over the centerline L2. The second part 1337 meanders in a U-pattern in the first direction D1 in a region over the centerline L2 and also meanders in a U-pattern in the second direction D2 in a region under the centerline L2. In addition, in the second resistance portion 1332, the first part 1336 and the second part 1337 have shapes which are symmetric to each other with respect to the center c232 of the second resistance portion 1332 as its point of symmetry (i.e., the center of symmetry). A first end portion of the first resistance portion 1331 is connected to the power supply terminal 21 via a first wiring portion 1351 of the first wiring pattern portion 135. A second end portion of the first resistance portion 1331 is connected to a second end portion of the second resistance portion 1332 via the fifth wiring pattern portion 139. A first end portion of the second resistance portion 1332 is connected to the second output terminal 24 via the fourth wiring pattern portion 138.

The fourth magnetoresistance pattern portion 134 includes a first resistance portion 1341 and a second resistance portion 1342. Each of the first resistance portion 1341 and the second resistance portion 1342 is formed in a meandering shape when viewed in the third direction D3 (i.e., the direction perpendicular to the paper sheet on which FIG. 16 is drawn). The first resistance portion 1341 includes a first part 1346 and a second part 1347. The first part 1346 meanders in a U-pattern in the first direction D1 in a region under the centerline L2 and also meanders in a U-pattern in the second direction D2 in a region over the centerline L2. The second part 1347 meanders in a U-pattern in the first direction D1 in a region over the centerline L2 and also meanders in a U-pattern in the second direction D2 in a region under the centerline L2. The second resistance portion 1342 includes a first part 1348 and a second part 1349. The first part 1348 meanders in a U-pattern in the first direction D1 in a region under the centerline L2 and also meanders in a U-pattern in the second direction D2 in a region over the centerline L2. The second part 1349 meanders in a U-pattern in the first direction D1 in a region over the centerline L2 and also meanders in a U-pattern in the second direction D2 in a region under the centerline L2. In addition, in the second resistance portion 1342, the first part 1348 and the second part 1349 have shapes which are symmetric to each other with respect to the center c242 of the second resistance portion 1342 as its point of symmetry (i.e., the center of symmetry). A first end portion of the first resistance portion 1341 is connected to the ground terminal 22 via a first wiring portion 1361 of the second wiring pattern portion 136. A second end portion of the first resistance portion 1341 is connected to a second end portion of the second resistance portion 1342 via a second wiring portion 1362 of the second wiring pattern portion 136. A first end portion of the second resistance portion 1342 is connected to the second output terminal 24 via the fourth wiring pattern portion 138.

In the magnetic sensor according to the second embodiment, the center c212 of the second resistance portion 1312 of the first magnetoresistance pattern portion 131 agrees with the centroid c112 thereof when viewed in the third direction D3 and the center c221 of the first resistance portion 1321 of the second magnetoresistance pattern portion 132 agrees with the centroid c121 thereof when viewed in the third direction D3. Also, the center c222 of the second resistance portion 1322 of the second magnetoresistance pattern portion 132 agrees with the centroid c122 thereof when viewed in the third direction D3 and the center c231 of the first resistance portion 1331 of the third magnetoresistance pattern portion 133 agrees with the centroid c131 thereof when viewed in the third direction D3. Furthermore, the center c232 of the second resistance portion 1332 of the third magnetoresistance pattern portion 133 agrees with the centroid c132 thereof when viewed in the third direction D3. Also, the center c242 of the second resistance portion 1342 of the fourth magnetoresistance pattern portion 134 agrees with the centroid c142 thereof when viewed in the third direction D3.

That is to say, in the magnetic sensor according to the second embodiment, the respective centroids c112, c121, c122, c131, c132, and c142 of the plurality of magnetoresistance pattern portions 131-134 are all located on the centerline L2 of the plurality of magnetoresistance pattern portions 131-134 in the second direction D2 when viewed in the third direction D3. More specifically, the centroid c112 of the second resistance portion 1312 of the first magnetoresistance pattern portion 131 is located on the centerline L2. Also, the centroid c121 of the first resistance portion 1321 of the second magnetoresistance pattern portion 132 and the centroid c122 of the second resistance portion 1322 of the second magnetoresistance pattern portion 132 are located on the centerline L2. Furthermore, the centroid c131 of the first resistance portion 1331 of the third magnetoresistance pattern portion 133 and the centroid c132 of the second resistance portion 1332 of the third magnetoresistance pattern portion 133 are located on the centerline L2. Furthermore, the centroid c142 of the second resistance portion 1342 of the fourth magnetoresistance pattern portion 134 is located on the centerline L2.

In this case, in the magnetic sensor according to the second variation of the first embodiment shown in FIG. 9 and the magnetic sensor according to the second embodiment, as well as the magnetic sensor 1 according to the first embodiment and the magnetic sensor according to the first variation described above, each of the magnetoresistance pattern portions 131-134 is configured as, for example, an artificial lattice film in which magnetic layers, each containing an NiFeCo alloy, and non-magnetic layers, each containing a Cu alloy, are alternately stacked one on top of another.

Also, in the magnetic sensor according to the second variation of the first embodiment shown in FIG. 9, each magnetoresistance pattern portion 131-134 may have a line width equal to or greater than 10 μm and equal to or less than 30 μm, for example. In the magnetic sensor according to the second variation of the first embodiment, a bridge circuit formed by these magnetoresistance pattern portions 131-134 may have a resistance value equal to or greater than 1 kΩ and equal to or less than 5 kΩ, for example.

In contrast, in the magnetic sensor according to the second embodiment, each magnetoresistance pattern portion 131-134 may have a line width W1 (refer to FIG. 17) equal to or greater than 4 μm and equal to or less than 15 μm, for example. Each magnetoresistance pattern portion 131-134 preferably has a line width W1 of 5 μm. In addition, the line width W1 of each magnetoresistance pattern portion 131-134 of the magnetic sensor according to the second embodiment is one half as long as the line width of each magnetoresistance pattern portion 131-134 of the magnetic sensor according to the second variation of the first embodiment. Thus, if the line width of each magnetoresistance pattern portion 131-134 of the magnetic sensor according to the second variation of the first embodiment is 10 μm, then the line width W1 of each magnetoresistance pattern portion 131-134 of the magnetic sensor according to the second embodiment is 5 μm. In addition, in the magnetic sensor according to the second embodiment, the interval W2 between adjacent ones of the magnetoresistance pattern portions 131-134 may be 5 μm, for example. In the magnetic sensor according to the second embodiment, a bridge circuit formed by the respective magnetoresistance pattern portions 131-134 may have a resistance value equal to or greater than 5 kΩ and equal to or less than 10 kΩ, for example.

Decreasing the line width W1 of each magnetoresistance pattern portion 131-134 as much as in the magnetic sensor according to the second embodiment enables increasing the resistance values of the plurality of magnetoresistance pattern portions 131-134. This may cut down power consumption required to deliver desired signal output. That is to say, the magnetic sensor according to the second embodiment may increase signal output per power consumption.

In addition, in the magnetic sensor according to the second embodiment, part of the second resistance portion 1342 of the fourth magnetoresistance pattern portion 134, for example, protrudes, in the first direction D1, toward the second resistance portion 1322, which is adjacent to the second resistance portion 1342 in the first direction D1, to overlap, in the second direction D2, with the second resistance portion 1322 of the second magnetoresistance pattern portion 132 as shown in FIG. 17. This makes the pattern width W3 of the second resistance portion 1342 of the fourth magnetoresistance pattern portion 134 equal to or greater than 15% and equal to or less than 25% of the cycle of magnetization λ (refer to FIG. 3) of the detection target 2. Consequently, this enables reducing the position detection error of the detection target 2. Note that the pattern width may also be made equal to or greater than 15% and equal to or less than 25% of the cycle of magnetization λ of the detection target 2 as for the first resistance portion 1311 and second resistance portion 1312 of the first magnetoresistance pattern portion 131, the first resistance portion 1321 and second resistance portion 1322 of the second magnetoresistance pattern portion 132, the first resistance portion 1331 and second resistance portion 1332 of the third magnetoresistance pattern portion 133, and the first resistance portion 1341 of the fourth magnetoresistance pattern portion 134 as well.

(3) Advantages

In the magnetic sensor according to the second embodiment, the pattern width W3 (refer to FIG. 5) of each of the plurality of magnetoresistance pattern portions 131-134 is equal to or greater than 15% of the cycle of magnetization λ (refer to FIG. 3) of the detection target 2. This makes the reaction of the detection target 2 to a change in flux density due to its relative movement much less steep than in a situation where the pattern width W3 of each of the plurality of magnetoresistance pattern portions 131-134 is less than 15% of the cycle of magnetization λ of the detection target 2. Consequently, this enables reducing the error to be caused by waveform distortion. In addition, in the magnetic sensor according to the second embodiment, each of the plurality of magnetoresistance pattern portions 131-134 is adjacent, in the first direction D1, to a neighboring magnetoresistance pattern portion and includes a part protruding in the first direction D1 toward the neighboring magnetoresistance pattern portion to overlap, in the second direction D2, with a part of the neighboring magnetoresistance pattern portion as described above. This shortens the gap distance between adjacent ones of the magnetoresistance pattern portions 131-134, thus contributing to downsizing the magnetic sensor 1. That is to say, the magnetic sensor according to the second embodiment contributes to downsizing while reducing the error to be caused by waveform distortion.

Furthermore, if the pattern width W3 of each of the plurality of magnetoresistance pattern portions 131-134 were greater than 25% of the cycle of magnetization λ of the detection target 2, then two adjacent magnetoresistance pattern portions would react simultaneously to the same magnetic pole of the detection target 2, thus possibly causing a decline in the positioning accuracy of the detection target 2. In contrast, in the magnetic sensor according to the second embodiment, the pattern width W3 of each of the plurality of magnetoresistance pattern portions 131-134 is equal to or less than 25% of the cycle of magnetization λ of the detection target 2. This reduces the chances of causing a decline in the positioning accuracy of the detection target 2.

(Aspects)

The embodiments and their variations described above are specific implementations of the following aspects of the present disclosure.

A magnetic sensor (1) according to a first aspect is configured to detect a position of a detection target (2) based on a change in magnetic field strength to be caused by relative movement of the detection target (2) in a first direction (D1). The detection target (2) is magnetized in the first direction (D1) in a predetermined cycle of magnetization (λ). The magnetic sensor (1) includes a plurality of magnetoresistance pattern portions (131-134). The plurality of magnetoresistance pattern portions (131-134) forms a bridge circuit. The plurality of magnetoresistance pattern portions (131-134) are arranged side by side in the first direction (D1). Each of the plurality of magnetoresistance pattern portions (131-134) is formed in a second direction (D2) perpendicular to the first direction (D1). Each of the plurality of magnetoresistance pattern portions (131-134) is formed in a meandering shape when viewed in a third direction (D3). The third direction (D3) is perpendicular to both the first direction (D1) and the second direction (D2). Centroids (c11-c14) of the plurality of magnetoresistance pattern portions (131-134) are located on a centerline (L2) of the plurality of magnetoresistance pattern portions (131-134) in the second direction (D2) when viewed in the third direction (D3).

This aspect contributes to downsizing the magnetic sensor (1).

In a magnetic sensor (1) according to a second aspect, which may be implemented in conjunction with the first aspect, each of the plurality of magnetoresistance pattern portions (131-134) has a pattern width (W3) that is equal to or greater than 15% and equal to or less than 25% of the cycle of magnetization (k).

This aspect reduces an error to be caused by waveform distortion.

In a magnetic sensor (1) according to a third aspect, which may be implemented in conjunction with the second aspect, each of the plurality of magnetoresistance pattern portions (131-134) is adjacent, in the first direction (D1), to a neighboring magnetoresistance pattern portion and includes a part protruding in the first direction (D1) toward the neighboring magnetoresistance pattern portion to overlap, in the second direction (D2), with a part of the neighboring magnetoresistance pattern portion.

This aspect contributes to further downsizing the magnetic sensor (1).

A magnetic sensor (1) according to a fourth aspect, which may be implemented in conjunction with any one of the first to third aspects, includes four magnetoresistance pattern portions (131, 132, 133, 134) as the plurality of magnetoresistance pattern portions (131, 132, 133, 134). The four magnetoresistance pattern portions (131, 132, 133, 134) form a full-bridge circuit as the bridge circuit.

A magnetic sensor (1) according to a fifth aspect, which may be implemented in conjunction with the fourth aspect, further includes a first wiring pattern portion (135), a second wiring pattern portion (136), a third wiring pattern portion (137), and a fourth wiring pattern portion (138). The first wiring pattern portion (135) is connected to a power supply terminal (21). The second wiring pattern portion (136) is connected to a ground terminal (22). The third wiring pattern portion (137) is connected to a first output terminal (23). The fourth wiring pattern portion (138) is connected to a second output terminal (24). The plurality of magnetoresistance pattern portions (131-134) includes: a first magnetoresistance pattern portion (131) and a second magnetoresistance pattern portion (132) which are connected together in series; and a third magnetoresistance pattern portion (133) and a fourth magnetoresistance pattern portion (134) which are connected together in series. The first wiring pattern portion (135) is connected to not only one end portion, located opposite from another end portion adjacent to the second magnetoresistance pattern portion (132), of the first magnetoresistance pattern portion (131) but also one end portion, located opposite from another end portion adjacent to the fourth magnetoresistance pattern portion (134), of the third magnetoresistance pattern portion (133). The second wiring pattern portion (136) is connected to not only one end portion, located opposite from another end portion adjacent to the first magnetoresistance pattern portion (131), of the second magnetoresistance pattern portion (132) but also portion, located opposite from another end portion adjacent to the third magnetoresistance pattern portion (133), of the fourth magnetoresistance pattern portion (134). The third wiring pattern portion (137) is connected to the first magnetoresistance pattern portion (131) and the second magnetoresistance pattern portion (132). The fourth wiring pattern portion (138) is connected to the third magnetoresistance pattern portion (133) and the fourth magnetoresistance pattern portion (134).

Note that the constituent elements according to the second to fifth aspects are not essential constituent elements for the magnetic sensor (1) but may be omitted as appropriate.

A magnetic sensor (1) according to a sixth aspect is configured to detect a position of a detection target (2) based on a change in magnetic field strength to be caused by relative movement of the detection target (2) in a first direction (D1). The detection target (2) is magnetized in the first direction (D1) in a predetermined cycle of magnetization (λ). The magnetic sensor (1) includes a plurality of magnetoresistance pattern portions (131-134). The plurality of magnetoresistance pattern portions (131-134) forms a bridge circuit. The plurality of magnetoresistance pattern portions (131-134) are arranged side by side in the first direction (D1). Each of the plurality of magnetoresistance pattern portions (131-134) is formed in a second direction (D2) perpendicular to the first direction (D1). Each of the plurality of magnetoresistance pattern portions (131-134) has a pattern width (W3) that is equal to or greater than 15% and equal to or less than 25% of the cycle of magnetization (k). Each of the plurality of magnetoresistance pattern portions (131-134) is formed in a meandering shape when viewed in a third direction (D3). The third direction (D3) is perpendicular to both the first direction (D1) and the second direction (D2). Each of the plurality of magnetoresistance pattern portions (131-134) is adjacent, in the first direction (D1), to a neighboring magnetoresistance pattern portion and includes a part protruding in the first direction (D1) toward the neighboring magnetoresistance pattern portion to overlap, in the second direction (D2), with a part of the neighboring magnetoresistance pattern portion.

This aspect contributes to downsizing the magnetic sensor (1) while reducing an error to be caused by waveform distortion.

### REFERENCE SIGNS LIST

1 Magnetic Sensor
2 Detection Target
21 Power Supply Terminal
22 Ground Terminal
23 First Output Terminal
24 Second Output Terminal
131 First Magnetoresistance Pattern Portion (Magnetoresistance Pattern Portion)
132 Second Magnetoresistance Pattern Portion (Magnetoresistance Pattern Portion)
133 Third Magnetoresistance Pattern Portion (Magnetoresistance Pattern Portion)
134 Fourth Magnetoresistance Pattern Portion (Magnetoresistance Pattern Portion)
135 First Wiring Pattern Portion
136 Second Wiring Pattern Portion
137 Third Wiring Pattern Portion
138 Fourth Wiring Pattern Portion
c11, c12, c13, c14 Centroid
c21, c22, c23, c24 Center
D1 First Direction
D2 Second Direction
D3 Third Direction
L2 Centerline
W3 Pattern Width
λ Cycle of Magnetization

1. A magnetic sensor configured to detect a position of a detection target based on a change in magnetic field strength to be caused by relative movement of the detection target in a first direction, the detection target being magnetized in the first direction in a predetermined cycle of magnetization,
the magnetic sensor comprising a plurality of magnetoresistance pattern portions that forms a bridge circuit,
the plurality of magnetoresistance pattern portions being arranged side by side in the first direction,
each of the plurality of magnetoresistance pattern portions being formed in a second direction perpendicular to the first direction,
each of the plurality of magnetoresistance pattern portions being formed in a meandering shape when viewed in a third direction perpendicular to both the first direction and the second direction,
centroids of the plurality of magnetoresistance pattern portions being located on a centerline of the plurality of magnetoresistance pattern portions in the second direction when viewed in the third direction.

2. The magnetic sensor of claim 1, wherein
each of the plurality of magnetoresistance pattern portions has a pattern width that is equal to or greater than 15% and equal to or less than 25% of the cycle of magnetization.

3. The magnetic sensor of claim 2, wherein
each of the plurality of magnetoresistance pattern portions is adjacent, in the first direction, to a neighboring magnetoresistance pattern portion and includes a part protruding in the first direction toward the neighboring magnetoresistance pattern portion to overlap, in the second direction, with a part of the neighboring magnetoresistance pattern portion.

4. The magnetic sensor of claim 1, comprising four magnetoresistance pattern portions as the plurality of magnetoresistance pattern portions, wherein
the four magnetoresistance pattern portions form a full-bridge circuit as the bridge circuit.

5. The magnetic sensor of claim 4, further comprising:
a first wiring pattern portion connected to a power supply terminal;
a second wiring pattern portion connected to a ground terminal;
a third wiring pattern portion connected to a first output terminal; and
a fourth wiring pattern portion connected to a second output terminal, wherein
the plurality of magnetoresistance pattern portions includes:
a first magnetoresistance pattern portion and a second magnetoresistance pattern portion which are connected together in series; and
a third magnetoresistance pattern portion and a fourth magnetoresistance pattern portion which are connected together in series,
the first wiring pattern portion is connected to not only one end portion, located opposite from another end portion adjacent to the second magnetoresistance pattern portion, of the first magnetoresistance pattern portion but also one end portion, located opposite from another end portion adjacent to the fourth magnetoresistance pattern portion, of the third magnetoresistance pattern portion,
the second wiring pattern portion is connected to not only one end portion, located opposite from another end portion adjacent to the first magnetoresistance pattern portion, of the second magnetoresistance pattern portion but also one end portion, located opposite from another end portion adjacent to the third magnetoresistance pattern portion, of the fourth magnetoresistance pattern portion,
the third wiring pattern portion is connected to the first magnetoresistance pattern portion and the second magnetoresistance pattern portion, and
the fourth wiring pattern portion is connected to the third magnetoresistance pattern portion and the fourth magnetoresistance pattern portion.
